(19) United States
(12) Patent Application Publication
(10) Pub. No.: US 2026/0073834 A1
(43) Pub. Date: Mar. 12, 2026

(54) SHIFT REGISTER, AND GATE DRIVE CIRCUIT AND DRIVING METHOD THEREFOR

(71) Applicants: Yungu (Gu’an) Technology Co., Ltd., Langfang (CN); Hefei Visionox Technology Co., Ltd., Hefei (CN)

(72) Inventors: Enqing GUO, Langfang (CN); Jianjun LU, Hefei (CN); Cuili GAI, Langfang (CN); Junfeng LI, Langfang (CN)

(73) Assignees: Yungu (Gu’an) Technology Co., Ltd., Langfang (CN); Hefei Visionox Technology Co., Ltd., Hefei (CN)

(21) Appl. No.: 19/387,553

(22) Filed: Nov. 12, 2025

Related U.S. Application Data
(63) Continuation of application No. PCT/CN2023/108510, filed on Jul. 21, 2023.

(30) Foreign Application Priority Data
Mar. 13, 2023 (CN) 202310238287.0

(51) Int. Cl. G09G 3/20; G11C 19/28

(52) U.S. Cl. CPC G09G 3/2092; G09G 2310/0267; G09G 2310/0286; G09G 2310/08; G11C 19/287

(57) ABSTRACT

Embodiments of the present application disclose a shift register, and a gate drive circuit and a driving method therefor. A first control module is configured to control, based on a signal of a first clock signal terminal, a signal of a second clock signal terminal, and a level of a second node, an initial signal and a first level signal to be transmitted to a first node. A second control module controls, based on the initial signal and a signal of a third clock signal terminal, a second level signal and the signal of the third clock signal terminal to be transmitted to the second node. An output module controls, based on a level of the first node, the signal of the second clock signal terminal to be transmitted to an output terminal of the shift register.

### CROSS-REFERENCE TO RELATED APPLICATIONS

The present application is a continuation of International Application No. PCT/CN2023/108510 filed on Jul. 21, 2023, which claims priority to Chinese Patent Application No. 202310238287.0, filed with the China National Intellectual Property Administration on Mar. 13, 2023, which are incorporated herein by reference in their entireties.

### FIELD

Embodiments of the present application relate to the field of display technologies, and in particular, to a shift register, and a gate drive circuit and a driving method therefor.

### BACKGROUND

A display panel includes a scanning circuit. The scanning circuit includes a plurality of stages of cascaded shift registers. Output terminals of the shift registers are connected to scanning lines, and the scanning circuit can output scan signals to the scanning lines.

However, the scan signals output by the scanning circuit have low flexibility.

### SUMMARY

The present application provides a shift register, and a gate drive circuit and a driving method therefor, to improve the flexibility of a scan signal output by a scanning circuit, to meet application requirements of a display panel.

In one embodiment of the present application provides a shift register, including: a first control module, a second control module, and an output module, where an output terminal of the first control module is connected to a first node, and an output terminal of the second control module is connected to a second node;
the first control module is configured to control, based on a signal of a first clock signal terminal, a signal of a second clock signal terminal, and a level of the second node, an initial signal and a first level signal to be transmitted to the first node;
the second control module is configured to control, based on the initial signal and a signal of a third clock signal terminal, a second level signal and the signal of the third clock signal terminal to be transmitted to the second node; and
the output module is configured to control, based on a level of the first node, the signal of the second clock signal terminal to be transmitted to an output terminal of the shift register, and control, based on the level of the second node, the first level signal to be transmitted to the output terminal of the shift register, where
an effective level pulse of the second clock signal terminal is delayed relative to an effective level pulse of the first clock signal terminal, and a delay time is greater than or equal to ½ of a time corresponding to the effective level pulse; an effective level pulse of the third clock signal terminal is delayed relative to the effective level pulse of the second clock signal terminal; and an effective level pulse of the initial signal overlaps with an effective level pulse of the signal of the first clock signal terminal.

In one embodiment of the present application further provides a gate drive circuit, including a plurality of stages of cascaded shift registers according to the embodiments, where the gate drive circuit further includes: a first clock signal line, a second clock signal line, a third clock signal line, and a fourth clock signal line, where the first clock signal line, the second clock signal line, the third clock signal line, and the fourth clock signal line are configured to transmit clock signals whose timings are sequentially delayed; a first clock signal terminal of a (4n-3)^{th} stage of shift register is connected to the first clock signal line, a second clock signal terminal of the (4n-3)^{th} stage of shift register is connected to the second clock signal line, and a third clock signal terminal of the (4n-3)^{th} stage of shift register is connected to the fourth clock signal line; a first clock signal terminal of a (4n-2)^{th} stage of shift register is connected to the second clock signal line, a second clock signal terminal of the (4n-2)^{th} stage of shift register is connected to the third clock signal line, and a third clock signal terminal of the (4n-2)^{th} stage of shift register is connected to the first clock signal line; a first clock signal terminal of a (4n-1)^{th} stage of shift register is connected to the third clock signal line, a second clock signal terminal of the (4n-1)^{th} stage of shift register is connected to the fourth clock signal line, and a third clock signal terminal of the (4n-1)^{th} stage of shift register is connected to the second clock signal line; a first clock signal terminal of a 4n^{th} stage of shift register is connected to the fourth clock signal line, a second clock signal terminal of the 4n^{th} stage of shift register is connected to the first clock signal line, and a third clock signal terminal of the 4n^{th} stage of shift register is connected to the third clock signal line, where n is an integer greater than or equal to 1, and 4n is less than or equal to a total number of shift registers; and the first clock signal line, the second clock signal line, the third clock signal line, and the fourth clock signal line are configured to transmit clock signals whose timings are sequentially delayed by a preset duration, where the preset duration is greater than or equal to ½ of a duration corresponding to an effective level pulse of the clock signal.

In one embodiment of the present application further provides a driving method for a gate drive circuit, including:
inputting an initial signal to a first control module, and inputting corresponding signals to a first clock signal terminal and a second clock signal terminal, and the first control module controls, based on the signal of the first clock signal terminal, the signal of the second clock signal terminal, and a level of a second node, the initial signal and a first level signal to be transmitted to a first node;
inputting the initial signal to a second control module, and inputting a corresponding signal to a third clock signal terminal, and the second control module controls, based on the initial signal and the signal of the third clock signal terminal, a second level signal and the signal of the third clock signal terminal to be transmitted to the second node; and controlling, by an output module based on a level of the first node, the signal of the second clock signal terminal to be transmitted to an output terminal of the shift register, and controlling, based on the level of the second node, the first level signal to be transmitted to the output terminal of the shift register, where
an effective level pulse of the second clock signal terminal is delayed relative to an effective level pulse of the first clock signal terminal, and a delay time is greater than or equal to ½ of a time corresponding to the effective level pulse; an effective level pulse of the third clock signal terminal is delayed relative to the effective level pulse of the second clock signal terminal; and an effective level pulse of the initial signal overlaps with an effective level pulse of the signal of the first clock signal terminal.

According to the shift register, and the gate drive circuit and the driving method therefor of the embodiments of the present application, more clock signals are introduced, and the first control module is configured to control, based on the signal of the first clock signal terminal, the signal of the second clock signal terminal, and the level of the second node, the initial signal and the first level signal to be transmitted to the first node; the second control module controls, based on the initial signal and the signal of the third clock signal terminal, the second level signal and the signal of the third clock signal terminal to be transmitted to the second node; and the output module controls, based on the level of the first node, the signal of the second clock signal terminal to be transmitted to the output terminal of the shift register. Additionally, the signal of the second clock signal terminal is delayed relative to the signal of the first clock signal terminal, and the delay time is greater than or equal to ½ of the time corresponding to the effective level pulse; the signal of the third clock signal terminal is delayed relative to the signal of the second clock signal terminal; the effective level pulse of the initial signal overlaps with the effective level pulse of the signal of the first clock signal terminal in timing, and effective level signals output by two adjacent stages of shift registers may be controlled to overlap or not overlap by controlling the overlap or non-overlap between the signal of the first clock signal terminal and the signal of the second clock signal terminal, thereby increasing the flexibility of the output of the gate drive circuit including the shift register of the embodiments to meet application requirements of a display panel.

### BRIEF DESCRIPTION OF THE DRAWINGS

FIG. 1 is a schematic diagram of a structure of a shift register according to an embodiment of the present application;

FIG. 2 is a schematic diagram of a structure of another shift register according to an embodiment of the present application;

FIG. 3 is a schematic diagram of a structure of another shift register according to an embodiment of the present application;

FIG. 4 is a schematic diagram of a structure of another shift register according to an embodiment of the present application;

FIG. 5 is a schematic diagram of a structure of another shift register according to an embodiment of the present application;

FIG. 6 is a schematic diagram of a structure of another shift register according to an embodiment of the present application;

FIG. 7 is a schematic diagram of a structure of another shift register according to an embodiment of the present application;

FIG. 8 is a working timing diagram of a shift register according to an embodiment of the present application;

FIG. 9 is a schematic diagram of a structure of another shift register according to an embodiment of the present application;

FIG. 10 is a schematic diagram of a structure of a display panel according to an embodiment of the present application;

FIG. 11 is a working timing diagram of another shift register according to an embodiment of the present application;

FIG. 12 is a working timing diagram of another shift register according to an embodiment of the present application;

FIG. 13 is a working timing diagram of another shift register according to an embodiment of the present application;

FIG. 14 is a schematic diagram of a structure of a gate drive circuit according to an embodiment of the present application;

FIG. 15 is a schematic diagram of driving timing of a gate drive circuit according to an embodiment of the present application;

FIG. 16 is a driving timing diagram of another display panel according to an embodiment of the present application;

FIG. 17 is a driving timing diagram of another display panel according to an embodiment of the present application;

FIG. 18 is a driving timing diagram of another display panel according to an embodiment of the present application;

FIG. 19 is a schematic diagram of a structure of another gate drive circuit according to an embodiment of the present application; and

FIG. 20 is a flowchart of a driving method for a gate drive circuit according to an embodiment of the present application.

### DETAILED DESCRIPTION OF THE EMBODIMENTS

The present application is further described in detail below with reference to the accompanying drawings and embodiments. It can be understood that specific embodiments described herein are used merely to explain the present application, rather than limit the present application. It should be additionally noted that, for ease of description, only some but not all structures related to the present application are shown in the drawings.

As described in the BACKGROUND, a scan signal output by a scanning circuit has low flexibility. The inventors have found that a reason for the above situation is that a shift register of the scanning circuit is connected to two clock signals, for example, a first clock signal and a second clock signal, respectively, where the first clock signal and the second clock signal are both signals that alternate between high and low levels, one of the high and low levels is an effective level, and the other level state is an ineffective level. For example, when all transistors in the shift register are P-type transistors, the low level is an effective level, and the high level is an ineffective level. To ensure that the shift register can work normally, the effective level pulses of the first clock signal and the second clock signal cannot overlap. Accordingly, scan signals output by stages of shift registers do not overlap; as a result, the scan signal output by the scanning circuit is relatively undiversified in form. If the shift register is applied to a display panel in which odd-numbered row pixel circuits and even-numbered row pixel circuits are connected to different data lines, two sets of scanning circuits need to be set up, which causes the scanning circuit to occupy a large border area and increases a number of devices in a border region, resulting in a large parasitic capacitance and an increased signal delay, and making it difficult to meet application requirements of the display panel.

Based on the above reasons, embodiments of the present application provide a shift register. FIG. 1 is a schematic diagram of a structure of a shift register according to an embodiment of the present application. Referring to FIG. 1, the shift register includes a first control module 110, a second control module 120, and an output module 130. An output terminal of the first control module 110 is connected to a first node N1, and an output terminal of the second control module 120 is connected to a second node N2. The first control module 110 is configured to control, based on a signal of a first clock signal terminal SCK1, a signal of a second clock signal terminal SCK2, and a level of the second node N2, an initial signal SIN and a first level signal VGH to be transmitted to the first node N1. The second control module 120 is configured to control, based on the initial signal SIN and a signal of a third clock signal terminal SCK3, a second level signal VGL and the signal of the third clock signal terminal SCK3 to be transmitted to the second node N2. The output module 130 is configured to control, based on a level of the first node N1, the signal of the second clock signal terminal SCK2 to be transmitted to an output terminal OUT of the shift register, and control, based on the level of the second node N2, the first level signal VGH to be transmitted to the output terminal OUT of the shift register.

An effective level pulse of the second clock signal terminal is delayed relative to an effective level pulse of the first clock signal terminal, and a delay time is greater than or equal to ½ of a time corresponding to the effective level pulse. An effective level pulse of the third clock signal terminal is delayed relative to the effective level pulse of the second clock signal terminal. An effective level pulse of the initial signal overlaps with an effective level pulse of the signal of the first clock signal terminal.

The first control module 110 being configured to control, based on the signal of the first clock signal terminal SCK1, the signal of the second clock signal terminal SCK2, and the level of the second node N2, the initial signal SIN and the first level signal VGH to be transmitted to the first node N1 specifically means that when the signal of the first clock signal terminal SCK1 is an effective level signal, the first control module 110 transmits the initial signal SIN to the first node N1; and in a period when the second node N2 is at an effective level and the signal of the second clock signal terminal SCK2 is an effective level signal, the first control module 110 transmits the first level signal VGH to the first node N1.

The second control module 120 being configured to control, based on the initial signal SIN and the signal of the third clock signal terminal SCK3, the second level signal VGL and the signal of the third clock signal terminal SCK3 to be transmitted to the second node N2 specifically means that when the initial signal SIN is an effective level signal, the second control module 120 transmits the signal of the third clock signal terminal SCK3 to the second node N2; and when the signal of the third clock signal terminal SCK3 is an effective level signal, the second control module 120 transmits the second level signal VGL to the second node N2.

The output module 130 being configured to control, based on the level of the first node N1, the signal of the second clock signal terminal SCK2 to be transmitted to the output terminal OUT of the shift register, and control, based on the level of the second node N2, the first level signal VGH to be transmitted to the output terminal OUT of the shift register specifically means that when the level of the first node N1 is an effective level, the output module 130 transmits the signal of the second clock signal terminal SCK2 to the output terminal of the shift register; and when the level of the second node N2 is an effective level, the output module 130 transmits the first level signal VGH to the output terminal of the shift register.

In one frame, the signal of the first clock signal terminal SCK1, the signal of the second clock signal terminal SCK2, and the signal of the third clock signal terminal SCK3 all include a plurality of high level pulses and a plurality of low level pulses, and alternate between high level pulses and low level pulses. In one embodiment, cycles of the signal of the first clock signal terminal SCK1, the signal of the second clock signal terminal SCK2, and the signal of the third clock signal terminal SCK3 are the same, high level pulse widths of the signal of the first clock signal terminal SCK1, the signal of the second clock signal terminal SCK2, and the signal of the third clock signal terminal SCK3 are equal, and low level pulse widths of the signal of the first clock signal terminal SCK1, the signal of the second clock signal terminal SCK2, and the signal of the third clock signal terminal SCK3 are equal. That is, waveforms of the signal of the first clock signal terminal SCK1, the signal of the second clock signal terminal SCK2, and the signal of the third clock signal terminal SCK3 are the same. The signal of the second clock signal terminal SCK2 is delayed relative to the signal of the first clock signal terminal SCK1, and the signal of the third clock signal terminal SCK3 is delayed relative to the signal of the second clock signal terminal SCK2. In one embodiment, high level voltage amplitudes of the signal of the first clock signal terminal SCK1, the signal of the second clock signal terminal SCK2, and the signal of the third clock signal terminal SCK3 are equal, and low level voltage amplitudes of the signal of the first clock signal terminal SCK1, the signal of the second clock signal terminal SCK2, and the signal of the third clock signal terminal SCK3 are equal.

In one frame, the initial signal SIN is a signal including a high level pulse and a low level pulse.

The signal of the first clock signal terminal SCK1, the signal of the second clock signal terminal SCK2, the signal of the third clock signal terminal SCK3, and the initial signal SIN are collectively referred to as control signals. For any control signal, an effective level signal of the control signal is determined by a device type of a module in the shift register controlled by the control signal. Specifically, the effective level signal of the control signal is a signal that may control a corresponding device to be turned on. For example, when the control signal is used to control a P-type transistor, the effective level signal is a low level signal; when the control signal is used to control an N-type transistor, the effective level signal is a high level signal.

The first level signal VGH and the second level signal VGL may both be constant signals, and the first level signal VGH and the second level signal VGL have opposite levels. In one embodiment, the first level signal VGH is a high level signal, and the second level signal VGL is a low level signal; or the first level signal VGH may be a low level signal, and the second level signal VGL may be a high level signal.

In one embodiment, for each control signal, voltage values of the high level signals may be equal, for example, may be +7 V, and voltage values of the low level signals may also be equal, for example, may be −7 V. Voltage values of the high level signals in the first level signal VGH and the second level signal VGL may also be +7 V, and voltage values of the low level signals may also be −7 V. In embodiments of the present application, description is provided by using an example in which the first level signal VGH is an ineffective level signal, and the second level signal VGL is an effective level signal.

In this embodiment, the signal of the second clock signal terminal SCK2 is delayed relative to the signal of the first clock signal terminal SCK1, and the signal of the third clock signal terminal SCK3 is delayed relative to the signal of the second clock signal terminal SCK2. The effective level pulse of the signal of the second clock signal terminal SCK2 may overlap or may not overlap with the effective level pulse of the signal of the first clock signal terminal SCK1. The effective level pulse of the signal of the third clock signal terminal SCK3 does not overlap with the effective level pulse of the signal of the second clock signal terminal SCK2.

In the case where the effective level pulse of the signal of the second clock signal terminal SCK2 overlaps with the effective level pulse of the signal of the first clock signal terminal SCK1, when the signal of the first clock signal terminal SCK1 is an effective level signal and the initial signal SIN is an effective level signal, the first control module 110 transmits the effective level signal of the initial signal SIN to the first node N1, and the output module 130 outputs the signal of the second clock signal terminal SCK2 to the output terminal of the shift register based on an effective level of the first node N1. Because the effective level pulse of the signal of the second clock signal terminal SCK2 overlaps with the effective level pulse of the signal of the first clock signal terminal SCK1, the output module 130 outputs the effective level signal of the signal of the second clock signal terminal SCK2 to the output terminal of the shift register in this case. Therefore, an effective level signal in an output signal of the output terminal OUT of the shift register overlaps with the effective level signal in the initial signal SIN. For a gate drive circuit, the initial signal SIN is an output signal of a previous stage of shift register. Therefore, the shift register of this embodiment may achieve overlap of effective level signals output by two adjacent stages of shift registers. In one embodiment, the effective level pulse of the signal of the third clock signal terminal SCK3 does not overlap with the effective level pulse of the signal of the second clock signal terminal SCK2. In this case, when the signal of the first clock signal terminal SCK1 is an effective level signal, and the initial signal SIN and the signal of the second clock signal terminal SCK2 are effective level signals, the signal of the third clock signal terminal SCK3 is an ineffective level signal. The second control module 120 transmits the ineffective level signal of the signal of the third clock signal terminal SCK3 to the second node N2 based on the effective level signal of the initial signal SIN, and the output module 130 does not output the first level signal VGH. In this way, the effective level signal output of the signal of the second clock signal terminal SCK2 is not affected. From the above analysis, it can be learned that in a gate drive circuit including the shift register of this embodiment, when the effective level pulse of the signal of the second clock signal terminal SCK2 overlaps with the effective level pulse of the signal of the first clock signal terminal SCK1, effective level signals output by two adjacent stages of shift registers may overlap. When the effective level signals output by the two adjacent stages of shift registers may overlap, the shift register is applied to a display panel in which odd-numbered and even-numbered row pixel circuits are connected to different data lines. In this case, a set of gate drive circuits may be disposed in the display panel, which occupies a small border area, reduces a signal delay, and can meet application requirements of the display panel.

In the case where the effective level pulse of the signal of the second clock signal terminal SCK2 does not overlap with the effective level pulse of the signal of the first clock signal terminal SCK1, when the signal of the first clock signal terminal SCK1 is an effective level signal and the initial signal SIN is an effective level signal, the first control module 110 transmits the effective level signal of the initial signal SIN to the first node N1, and the output module 130 outputs the signal of the second clock signal terminal SCK2 to the output terminal of the shift register based on the effective level of the first node N1. Because the effective level pulse of the signal of the second clock signal terminal SCK2 does not overlap with the effective level pulse of the signal of the first clock signal terminal SCK1, the signal of the second clock signal terminal SCK2 is an ineffective level signal and the output of the shift register is an ineffective level signal in this case. That is, when the signal of the first clock signal terminal SCK1 is an effective level signal and the initial signal SIN is an effective level signal, the signal output by the shift register is an ineffective level signal; when the effective level signal of the shift register needs to be output when the signal of the second clock signal terminal SCK2 jumps to an effective level signal, and the signal of the second clock signal terminal SCK2 jumps to an effective level, the signal of the first clock signal terminal SCK1 is an ineffective level, and the effective level pulse of the initial signal SIN overlaps with an effective level pulse of the signal of the first clock signal terminal SCK1 (that is, the effective level pulse of the initial signal SIN completely overlaps with an effective level pulse of the signal of the first clock signal terminal SCK1). Accordingly, the initial signal SIN is at an ineffective level. Therefore, when the shift register outputs an effective level pulse, the initial signal SIN is at an ineffective level. For a gate drive circuit, the initial signal SIN is an output signal of a previous stage of shift register. Therefore, the shift register of this embodiment may achieve non-overlap between effective level signals output by two adjacent stages of shift registers.

The gate drive circuit to which the shift register of this embodiment is applicable may be a scanning circuit or a light emitting control circuit, to increase the flexibility of signals output by the scanning circuit and the light emitting control circuit.

In the shift register of this embodiment, more clock signals are introduced, and the first control module is configured to control, based on the signal of the first clock signal terminal, the signal of the second clock signal terminal, and the level of the second node, the initial signal and the first level signal to be transmitted to the first node; the second control module controls, based on the initial signal and the signal of the third clock signal terminal, the second level signal and the signal of the third clock signal terminal to be transmitted to the second node; and the output module controls, based on the level of the first node, the signal of the second clock signal terminal to be transmitted to the output terminal of the shift register. Additionally, the signal of the second clock signal terminal is delayed relative to the signal of the first clock signal terminal, and the delay time is greater than or equal to ½ of the time corresponding to the effective level pulse; the signal of the third clock signal terminal is delayed relative to the signal of the second clock signal terminal; the effective level pulse of the initial signal overlaps with the effective level pulse of the signal of the first clock signal terminal in timing, and effective level signals output by two adjacent stages of shift registers may be controlled to overlap or not overlap by controlling the overlap or non-overlap between the signal of the first clock signal terminal and the signal of the second clock signal terminal, thereby increasing the flexibility of the output of the gate drive circuit including the shift register of the embodiments to meet application requirements of a display panel.

On the basis of the above embodiments, in one embodiment, the effective level pulse of the signal of the third clock signal terminal SCK3 does not overlap with the effective level pulse of the signal of the second clock signal terminal SCK2; the second control module 120 is specifically configured to set the level of the second node N2 to an ineffective level based on the signal of the third clock signal terminal SCK3 and the initial signal SIN after the level of the first node N1 jumps to an effective level and before the effective level pulse of the signal of the second clock signal terminal SCK2 arrives.

Specifically, after the level of the first node N1 jumps to an effective level, the output module 130 may transmit the signal of the second clock signal terminal SCK2 to the output terminal of the shift register based on the effective level of the first node N1. When the effective level pulse of the signal of the second clock signal terminal SCK2 arrives, the output module 130 transmits the effective level to the output terminal of the shift register. By configuring the effective level pulse of the signal of the third clock signal terminal SCK3 not to overlap with the effective level pulse of the signal of the second clock signal terminal SCK2, before the effective level pulse of the signal of the second clock signal terminal SCK2 arrives, the signal of the third clock signal terminal SCK3 jumps to an ineffective level signal, and before the effective level pulse of the signal of the second clock signal terminal SCK2 arrives, the second control module 120 sets the level of the second node N2 to an ineffective level based on the ineffective level signal of the signal of the third clock signal terminal SCK3 and the effective level signal of the initial signal SIN. In this way, the output module 130 cannot transmit the first level signal VGH to the output terminal of the shift register, thereby ensuring the stability of the output of the effective level pulse in the signal of the second clock signal terminal SCK2 to the output terminal of the shift register.

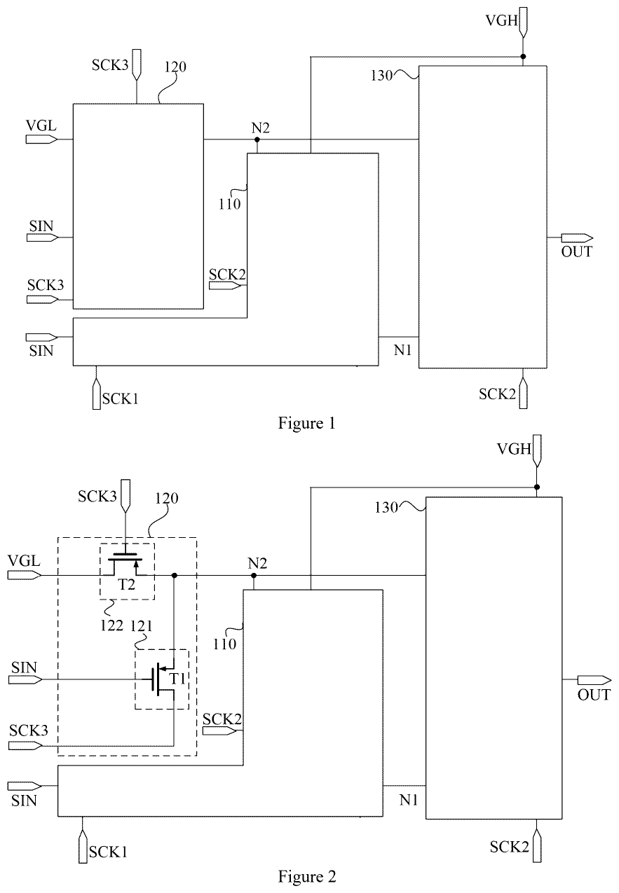

FIG. 2 is a schematic diagram of a structure of another shift register according to an embodiment of the present application. Referring to FIG. 2, in one embodiment, the second control module 120 includes a first control unit 121 and a second control unit 122. The first control unit 121 is configured to control, based on the initial signal SIN, the signal of the third clock signal terminal SCK3 to be transmitted to the second node N2, and the second control unit 122 is configured to control, based on the signal of the third clock signal terminal SCK3, the second level signal VGL to be transmitted to the second node N2.

Specifically, when the initial signal SIN is an effective level signal, the first control unit 121 is turned on and transmits the signal of the third clock signal terminal SCK3 to the second node N2; when the signal of the third clock signal terminal SCK3 is an effective level signal, the second control unit 122 is turned on and transmits the second level signal VGL to the second node N2. Because the signal of the third clock signal terminal SCK3 is delayed relative to the signal of the second clock signal terminal SCK2, the effective level pulses of the signal of the third clock signal terminal SCK3 and the signal of the second clock signal terminal SCK2 do not overlap. Therefore, when the signal of the second clock signal terminal SCK2 jumps from an ineffective level to an effective level, the signal of the third clock signal terminal SCK3 is still at an ineffective level. Before the signal of the second clock signal terminal SCK2 jumps from the ineffective level to the effective level, and when the signal of the third clock signal terminal SCK3 is at an ineffective level, by controlling the initial signal SIN to be at an effective level, the first control unit 121 is turned on and transmits the signal of the third clock signal terminal SCK3 at the ineffective level to the second node N2, and before the effective level pulse of the signal of the second clock signal terminal SCK2 arrives, the level of the second node N2 is set to an ineffective level based on the signal of the third clock signal terminal SCK3 and the initial signal SIN.

Still referring to FIG. 2, in one embodiment, the first control unit 121 includes a first transistor T1, where a gate of the first transistor T1 is connected to the initial signal SIN, a first electrode of the first transistor T1 is connected to the signal of the third clock signal terminal SCK3, and a second electrode of the first transistor T1 is electrically connected to the second node N2; and the second control unit 122 includes a second transistor T2, where a gate of the second transistor T2 is connected to the signal of the third clock signal terminal SCK3, a first electrode of the second transistor T2 is connected to the second level signal VGL, and a second electrode of the second transistor T2 is electrically connected to the second node N2.

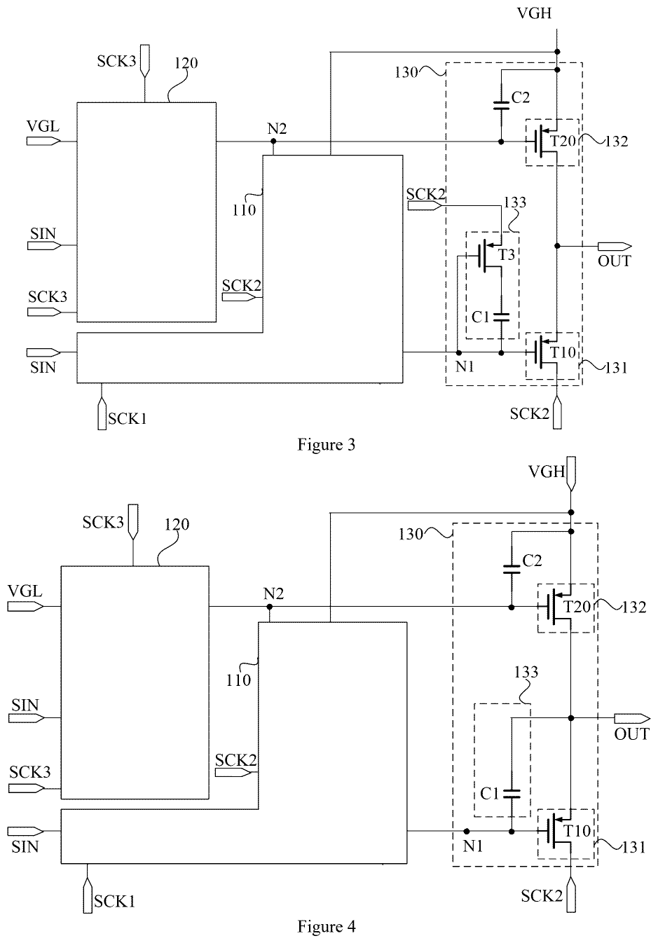

FIG. 3 is a schematic diagram of a structure of another shift register according to an embodiment of the present application. Referring to FIG. 3, in one embodiment, the output module 130 includes a first output unit 131 and a second output unit 132. A control terminal of the first output unit 131 is electrically connected to the first node N1, a first terminal of the first output unit 131 is connected to the signal of the second clock signal terminal SCK2, and a second terminal of the first output unit 131 is electrically connected to the output terminal of the shift register. A control terminal of the second output unit 132 is electrically connected to the second node N2, a first terminal of the second output unit 132 is connected to the first level signal VGH, and a second terminal of the second output unit 132 is electrically connected to the output terminal of the shift register.

Specifically, when the level of the first node N1 is at an effective level, the first output unit 131 is turned on to transmit the signal of the second clock signal terminal SCK2 to the output terminal of the shift register; and when the level of the second node N2 is an effective level, the second output unit 132 is turned on to transmit the first level signal VGH to the output terminal of the shift register. In one embodiment, the first output unit 131 includes a first output transistor T10, and the output module 130 further includes a storage capacitor C2. The second output unit 132 includes a second output transistor T20.

Still referring to FIG. 3, in one embodiment, the output module 130 further includes a bootstrap unit 133. In some embodiments of the present application, the bootstrap unit 133 is configured to couple the level of the first node N1 based on a voltage change of the signal of the second clock signal terminal SCK2.

Specifically, when the first node N1 is at an effective level, the first output unit 131 of the output module 130 may transmit the signal of the second clock signal terminal SCK2 to the output terminal of the shift register. However, because the effective level of the first node N1 is obtained by transmitting an effective level of the initial signal SIN, when the signals of the first node N1 and the second clock signal terminal SCK2 are both effective levels, a voltage value of the first node N1 and a voltage value of the signal of the second clock signal terminal SCK2 are almost equal (for example, both are −7 V), and therefore the first output transistor T10 of the first output unit 131 is only in a critical conduction state, and cannot completely transmit the effective level of the signal of the second clock signal terminal SCK2 to the output terminal of the shift register. As a result, a signal output by the output terminal OUT of the shift register cannot reach a voltage amplitude corresponding to the effective level of the signal of the second clock signal terminal SCK2. In this embodiment, the output module 130 is configured to further include a coupling unit, and when the voltage of the signal of the second clock signal terminal SCK2 changes, a potential of the first node N1 is also coupled to change accordingly. Using the first output transistor T10 being a P-type transistor and the corresponding effective level being a low level as an example, when the first node N1 is at an effective level and the signal of the second clock signal terminal SCK2 jumps from a high level to a low level, the level of the first node N1 is coupled and pulled lower, and the first output transistor T10 may be fully turned on, ensuring that the low level of the signal of the second clock signal terminal SCK2 can be normally transmitted to the output terminal of the shift register, and the output signal of the output terminal of the shift register can reach a voltage amplitude corresponding to the low level of the signal of the second clock signal terminal SCK2, for example, −7 V.

Still referring to FIG. 3, in one embodiment, the bootstrap unit 133 includes a third transistor T3 and a bootstrap capacitor C1, where a gate of the third transistor T3 is electrically connected to the first node N1, a first electrode of the third transistor T3 is connected to the signal of the second clock signal terminal SCK2, a second electrode of the third transistor T3 is connected to a first terminal of the bootstrap capacitor C1, and a second terminal of the bootstrap capacitor C1 is electrically connected to the first node N1.

Specifically, when the first node N1 is at an effective level, the third transistor T3 is turned on. During this phase, if the signal of the second clock signal terminal SCK2 jumps, a potential at the first terminal of the bootstrap capacitor C1 changes, and a potential at the second terminal of the bootstrap capacitor C1 also changes accordingly, thereby achieving the effect of coupling the potential of the first node N1 through the voltage change of the signal of the second clock signal terminal SCK2.

FIG. 4 is a schematic diagram of a structure of another shift register according to an embodiment of the present application. Referring to FIG. 4, in other embodiments of the present application, the bootstrap unit may include only a bootstrap capacitor C1, where a first terminal of the bootstrap capacitor C1 is connected to the output terminal of the shift register, and a second terminal of the bootstrap capacitor C1 is connected to the first node N1, thereby coupling a potential of the first node N1 through a potential change of the output terminal of the shift register.

It should be noted that, because the output terminal of the shift register needs to be connected to a scanning line in a display panel and the scanning line is connected to a plurality of pixel circuits, load on the output terminal OUT of the shift register is relatively large. Accordingly, an amplitude of a potential change of the output terminal of the shift register relative to a potential change of the signal of the second clock signal terminal SCK2 is reduced, and the potential change of the output terminal of the shift register needs to undergo a potential jump in the signal of the second clock signal terminal SCK2, which can only be reflected after being output by the first control unit. Therefore, the potential change of the output terminal of the shift register is slower than the potential change of the signal of the second clock signal terminal SCK2. Therefore, in this embodiment, the bootstrap unit 133 is directly connected to the signal of the second clock signal terminal SCK2, and the level of the first node N1 is coupled based on the voltage change of the signal of the second clock signal terminal SCK2. In one embodiment, the potential of the first node N1 may be coupled to have a larger voltage change amplitude. In another embodiment, the first node N1 may be quickly coupled to change based on the level jump of the signal of the second clock signal terminal SCK2. In this way, when the signal of the second clock signal terminal SCK2 jumps from an ineffective level to an effective level, the output terminal of the shift register may also quickly output a voltage amplitude corresponding to the effective level signal of the signal of the second clock signal terminal SCK2, thereby ensuring the speed and stability of the output signal.

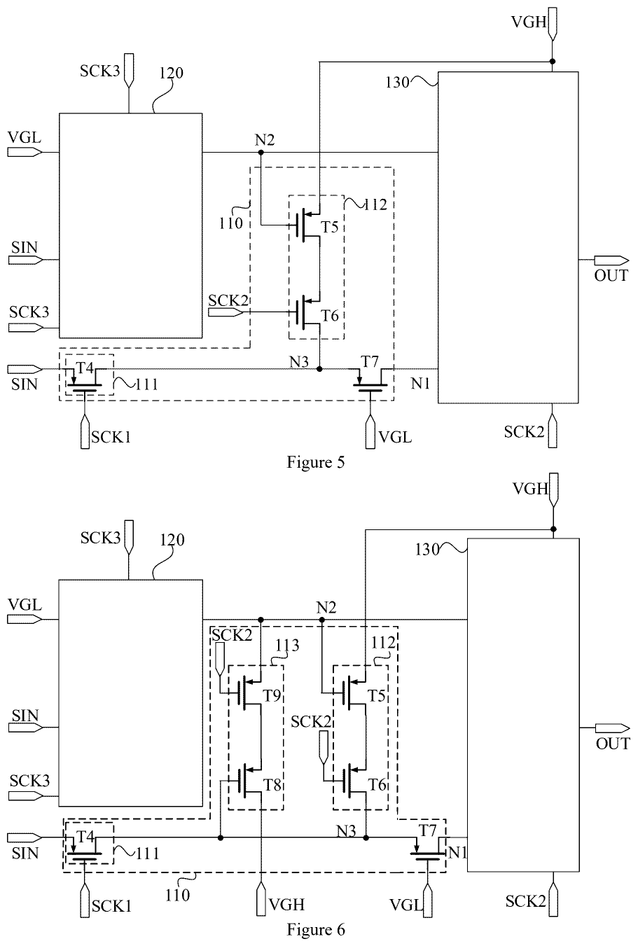

FIG. 5 is a schematic diagram of a structure of another shift register according to an embodiment of the present application. Referring to FIG. 5, in some embodiments of the present application, the first control module 110 includes an input unit 111 and a third control unit 112. The input unit 111 is configured to control, based on the signal of the first clock signal terminal SCK1 connected to a control terminal of the input unit, the initial signal SIN to be transmitted to the first node N1. The third control unit 112 is configured to control, based on the level of the second node N2 and the signal of the second clock signal terminal SCK2, the first level signal VGH to be transmitted to the first node N1.

Specifically, when the signal of the first clock signal terminal SCK1 is an effective level signal, the input unit 111 is turned on and transmits the initial signal SIN to the first node N1; and when the level of the second node N2 is an effective level and the signal of the second clock signal terminal SCK2 is an effective level signal, the third control unit 112 transmits the first level signal VGH to the first node N1.

Still referring to FIG. 5, on the basis of the above embodiments, in one embodiment, the input unit 111 includes a fourth transistor T4, where a gate of the fourth transistor T4 is connected to the signal of the first clock signal terminal SCK1, a first electrode of the fourth transistor T4 is connected to the initial signal SIN, and a second electrode of the fourth transistor T4 is electrically connected to the first node N1.

In one embodiment, the third control unit 112 includes a fifth transistor T5 and a sixth transistor T6, where a gate of the fifth transistor T5 is electrically connected to the second node N2, a first electrode of the fifth transistor T5 is connected to the first level signal VGH, and a second electrode of the fifth transistor T5 is electrically connected to a first electrode of the sixth transistor T6; and a gate of the sixth transistor T6 is connected to the signal of the second clock signal terminal SCK2, and a second electrode of the sixth transistor T6 is electrically connected to the first node N1.

In one embodiment, the first control module 110 further includes a seventh transistor T7, where a gate of the seventh transistor T7 is connected to the second level signal VGL, and the second electrode of the fourth transistor T4 and the second electrode of the sixth transistor T6 are both electrically connected to the first node N1 via the seventh transistor T7. Using the seventh transistor T7 being a P-type transistor as an example, the seventh transistor T7 may be configured such that when the level of the first node N1 is coupled to an extremely low level by the bootstrap unit of the output module 130, the extremely low level is isolated by the seventh transistor T7 and is not transmitted to the third node N3, thereby protecting the fourth transistor T4 and the sixth transistor T6 from being damaged due to an excessive voltage difference, and improving the reliability of the shift register.

FIG. 6 is a schematic diagram of a structure of another shift register according to an embodiment of the present application. Referring to FIG. 6, on the basis of the above embodiments, in some embodiments of the present application, the first control module 110 further includes a fourth control unit 113. The fourth control unit 113 is configured to control, based on a potential of the first node N1 and the signal of the second clock signal terminal SCK2, the first level signal VGH to be transmitted to the second node N2.

The fourth control unit 113 being configured to control, based on the potential of the first node N1 and the signal of the second clock signal terminal SCK2, the first level signal VGH to be transmitted to the second node N2 specifically means that when the potential of the first node N1 is an effective potential signal and the signal of the second clock signal terminal SCK2 is an effective potential signal, the fourth control unit 113 transmits the first level signal VGH to the second node N2.

In one embodiment, the fourth control unit 113 includes an eighth transistor T8 and a ninth transistor T9, where a gate of the eighth transistor T8 is electrically connected to the first node N1, a first electrode of the eighth transistor T8 is connected to the first level signal VGH, and a second electrode of the eighth transistor T8 is electrically connected to a first electrode of the ninth transistor T9; and a gate of the ninth transistor T9 is connected to the second clock signal terminal SCK2, and a second electrode of the ninth transistor T9 is electrically connected to the second node N2.

Specifically, when the potential of the first node N1 is an effective potential, the eighth transistor T8 is turned on; when the second clock signal is an effective level signal, the ninth transistor T9 is turned on. When the eighth transistor T8 and the ninth transistor T9 are both turned on, the first level signal VGH arrives at the second node N2 via the eighth transistor T8 and the ninth transistor T9.

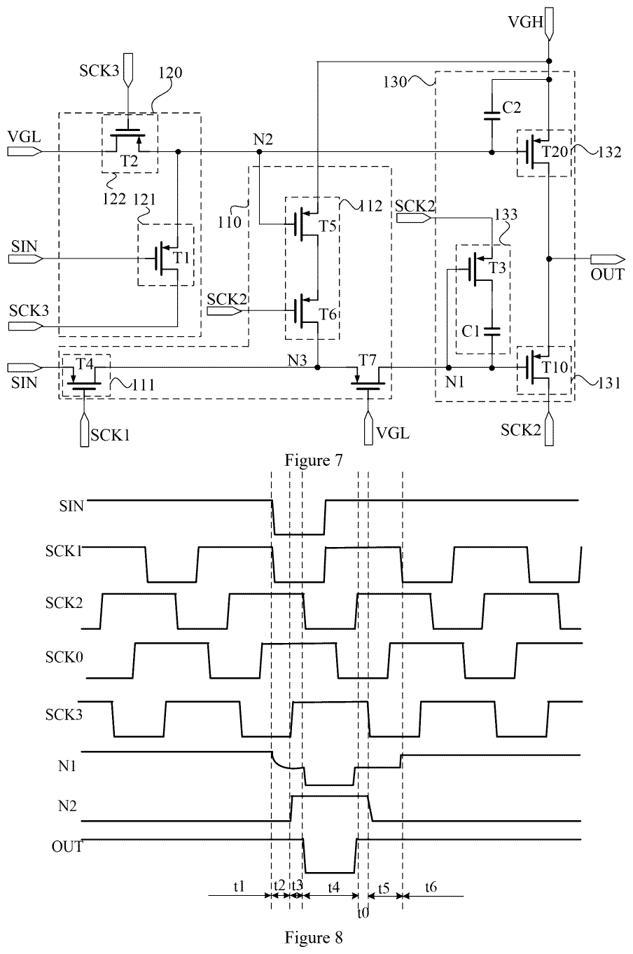

FIG. 7 is a schematic diagram of a structure of another shift register according to an embodiment of the present application. Referring to FIG. 7, the shift register includes a first control module 110, a second control module 120, and an output module 130. The second control module 120 includes a first control unit 121 and a second control unit 122. The first control unit 121 includes a first transistor T1, and the second control unit 122 includes a second transistor T2. The output module 130 includes a first output unit 131 and a second output unit 132. The first output unit 131 includes a first output transistor T10, and the second output unit 132 includes a second output transistor T20. The output module 130 further includes a bootstrap unit 133. The bootstrap unit 133 includes a third transistor T3 and a bootstrap capacitor C1. The first control module 110 includes an input unit 111 and a third control unit 112, where the input unit 111 includes a fourth transistor T4, and the third control unit 112 includes a fifth transistor T5 and a sixth transistor T6. The first control module 110 further includes a seventh transistor T7. FIG. 8 is a working timing diagram of a shift register according to an embodiment of the present application. The working timing is applicable to the shift register shown in FIG. 7. Using all the transistors in the shift register shown in FIG. 7 being P-type transistors as an example, the first level signal VGH is a high level signal, and the second level signal VGL is a low level signal. Referring to FIG. 7 and FIG. 8, a working process of the shift register includes the following phases.

In a first phase t1, the initial signal SIN is always at a high level. When the signal of the first clock signal terminal SCK1 is at a low level, the fourth transistor T4 is turned on, and the high level initial signal SIN is transmitted to the third node N3, and transmitted to the first node N1 via the seventh transistor T7, and the first output transistor T10 is turned off. When the signal of the third clock signal terminal SCK3 is at a low level, the second transistor T2 is turned on and transmits the second level signal VGL (low level signal) to the second node N2. The second output transistor T20 is turned on in response to the low level signal of the second node N2, and transmits the first level signal VGH (high level signal) to the output terminal of the shift register. That is, in the first phase t1, a signal output from the output terminal of the shift register is a high level signal.

In a second phase t2, the initial signal SIN and the signal of the first clock signal terminal SCK1 are both at low levels, the signal of the second clock signal terminal SCK2 is at a high level, and the signal of the third clock signal terminal SCK3 is at a low level. The first transistor T1 is turned on in response to the low level initial signal SIN, and transmits the low level signal of the third clock signal terminal SCK3 to the second node N2. The second transistor T2 is turned on in response to the low level signal of the third clock signal terminal SCK3, and transmits the second level signal VGL (low level signal) to the second node N2. At the same time, the fourth transistor T4 is turned on in response to the low level signal of the first clock signal terminal SCK1, and transmits the low level initial signal SIN to the first node N1. The first output transistor T10 is turned on in response to the low level of the first node N1, and transmits the high level signal of the second clock signal terminal SCK2 to the output terminal of the shift register. The second output transistor T20 is turned on in response to the low level of the second node N2, and transmits the first level signal VGH (high level signal) to the output terminal of the shift register. Therefore, in the second phase t2, the output signal of the output terminal of the shift register is a high level signal.

In a third phase t3, the initial signal SIN and the signal of the first clock signal terminal SCK1 remain at low levels, the signal of the second clock signal terminal SCK2 remains at a high level, and the signal of the third clock signal terminal SCK3 jumps from a low level to a high level. The first transistor T1 is turned on in response to the low level initial signal SIN, and transmits the high level signal of the third clock signal terminal SCK3 to the second node N2, and the second output transistor T20 is turned off, and the fifth transistor T5 is turned off at the same time. In this phase, the fourth transistor T4 is still turned on in response to the low level signal of the first clock signal terminal SCK1, and transmits the low level initial signal SIN to the first node N1, and the first output transistor T10 is turned on and transmits the high level signal of the second clock signal terminal SCK2 to the output terminal of the shift register. Therefore, in the third phase t3, the output signal of the output terminal of the shift register is a high level signal. Through the analysis of the working process of the third phase t3, it can be learned that when effective level pulses of the signal of the first clock signal terminal SCK1 and the signal of the second clock signal terminal SCK2 overlap, and an effective level pulse of the signal of the third clock signal terminal SCK3 does not overlap with the signal of the second clock signal terminal SCK2, the second node N2 may be pulled to a high level by the jump of the signal of the third clock signal terminal SCK3, without the need to pull the second node N2 to an ineffective level by an intermediate state process in the related art in which the signal of the second clock signal terminal SCK2 still needs to remain at a high level after the signal of the first clock signal terminal SCK1 jumps from a low level to a high level.

In a fourth phase t4, the signal of the second clock signal terminal SCK2 jumps from a high level to a low level. During the period when the initial signal SIN and the signal of the first clock signal terminal SCK1 remain at low levels, the fourth transistor T4 is still turned on in response to the low level signal of the first clock signal terminal SCK1, and transmits the low level initial signal SIN to the first node N1, and the first output transistor T10 is turned on, and transmits the low level signal of the second clock signal terminal SCK2 to the output terminal of the shift register. That is, the output signal of the output terminal OUT of the shift register jumps down to a low level in response to the signal of the second clock signal terminal SCK2. Because the third transistor T3 is also turned on based on a potential of the first node N1, the downward jump of the signal of the second clock signal terminal SCK2 causes the potential of the first node N1 to be coupled by a coupling capacitor to a level lower than the low level signal of the initial signal SIN, where an amplitude of the low level of the signal of the second clock signal terminal SCK2 is equal to an amplitude of the low level of the initial signal SIN, and the first output transistor T10 may be fully turned on, ensuring that the output signal of the output terminal OUT of the shift register can reach a voltage amplitude corresponding to the low level of the signal of the second clock signal terminal SCK2. Furthermore, during the period when the initial signal SIN and the signal of the first clock signal terminal SCK1 remain at low levels, the signal of the third clock signal terminal SCK3 is at a high level; therefore, the first transistor T1 is still turned on to transmit the high level signal of the third clock signal terminal SCK3 to the second node N2, and the second output transistor T20 is turned off. During the period when the initial signal SIN and the signal of the first clock signal terminal SCK1 jump to high levels, the first transistor T1 is turned off based on the high level initial signal SIN; when the initial signal SIN and the signal of the first clock signal terminal SCK1 are at high levels, the signal of the third clock signal terminal SCK3 is also at a high level, and therefore the second transistor T2 is turned off. The output module 130 includes a storage capacitor for maintaining the potential of the second node N2, and when the second control unit does not transmit a potential to the second node N2 (that is, when the first transistor T1 and the second transistor T2 may are both turned off), the storage capacitor may maintain the potential of the second node N2, and the second node N2 remains at a high level. Therefore, both the fifth transistor T5 and the second output transistor T20 are turned off in response to the high level of the second node N2. The fourth transistor T4 is turned off in response to the high level signal of the first clock signal terminal SCK1. Because the signal of the second clock signal terminal SCK2 is always at a low level, the potential of the first node N1 is maintained at a low level by the bootstrap capacitor C1, and the first output transistor T10 remains on, and continuously transmits the low level signal of the second clock signal terminal SCK2 to the output terminal of the shift register. Furthermore, before the signal of the third clock signal terminal SCK3 jumps to a low level, the shift register remains at the same level as the signal of the second clock signal terminal SCK2. Therefore, in the fourth phase t4, the output signal of the output terminal of the shift register is a low level signal.

There is a transition phase to between the fourth phase t4 and the fifth phase t5, which is caused by setting of a clock cycle, because the low level of the signal of the third clock signal terminal SCK3 does not arrive immediately after the phase t4. In the transition phase t0, the signal of the second clock signal terminal SCK2 jumps upward relative to the fourth stage t4, that is, the signal of the second clock signal terminal SCK2 jumps to a high level, and other control signals (including the signal of the first clock signal terminal SCK1, the signal of the third clock signal terminal SCK3, and the initial signal SIN) are not changed relative to the fourth stage t4; therefore, the second node N2 still maintains the high level of the fourth stage t4, and the second output transistor T20 is still off. Because the signal of the second clock signal terminal SCK2 jumps upward relative to the fourth stage t0, the level of the first node N1 is coupled upward, but the amplitude of the coupled level of the first node N1 is limited; therefore, the first output transistor T10 may still be turned on to output the high level signal of the second clock signal terminal SCK2 to the output terminal OUT of the shift register.

In a fifth phase t5, the signal of the third clock signal terminal SCK3 jumps down to a low level, and the second transistor T2 is turned on in response to the low level signal of the third clock signal terminal SCK3, and transmits the second level signal VGL (low level signal) to the second node N2 of the shift register, and the fifth transistor T5 and the second output transistor T20 are turned on, and the second output transistor T20 transmits the first level signal VGH (high level signal) to the output terminal of the shift register. In this phase, the signal of the first clock signal terminal SCK1 and the signal of the second clock signal terminal SCK2 are both at high levels; therefore, the fourth transistor T4 is turned off, the sixth transistor T6 is also turned off, the first node N1 remains at a low level, and the first output transistor T10 is turned on and transmits the high level signal of the second clock signal terminal SCK2 to the output terminal of the shift register. Therefore, in the fifth phase t5, the output signal of the output terminal of the shift register is a high level signal.

In a sixth phase t6, the signal of the first clock signal terminal SCK1 jumps down to a low level, the initial signal SIN is at a high level, and the fourth transistor T4 is turned on in response to the low level signal of the first clock signal terminal SCK1 and transmits the high level initial signal SIN to the first node N1, and the third transistor T3 and the first output transistor T10 are turned off. The second node N2 is still at a low level, the second output transistor T20 is turned on, and the output terminal of the shift register keeps outputting the first level signal VGH (high level signal). Therefore, in the sixth phase t6, the output signal of the output terminal of the shift register is a high level signal.

It should be noted that the working timing shown in FIG. 8 is a situation where the effective level pulse of the signal of the first clock signal terminal SCK1 overlaps with the effective level pulse of the signal of the second clock signal terminal SCK2. It can be learned from the working timing shown in FIG. 8 that because the signal of the first clock signal terminal SCK1 overlaps with the signal of the second clock signal terminal SCK2, the output signal of the shift register overlaps with the initial signal SIN, and in the gate drive circuit, the initial signal SIN is an output signal of a previous stage of shift register. That is, in this embodiment, the signal of the first clock signal terminal SCK1 is set to overlap with the signal of the second clock signal terminal SCK2, and there may be overlap between effective level pulses of output signals of two adjacent stages of shift registers.

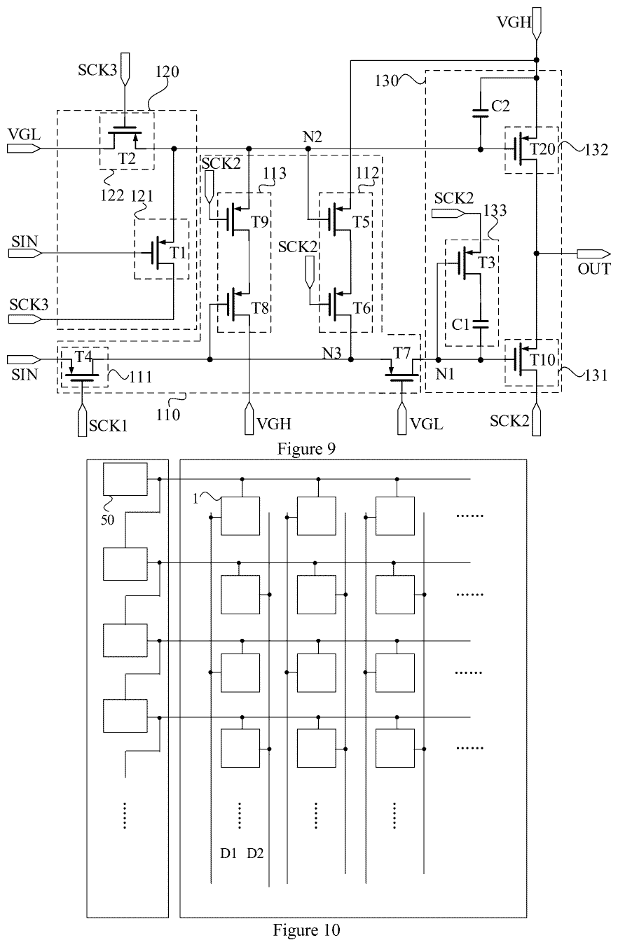

FIG. 9 is a schematic diagram of a structure of another shift register according to an embodiment of the present application. Referring to FIG. 9 and FIG. 7, similar to FIG. 7, the shift register shown in FIG. 9 includes a first control module 110, a second control module 120, and an output module 130. The second control module 120 includes a first control unit 121 and a second control unit 122. The first control unit 121 includes a first transistor T1, and the second control unit 122 includes a second transistor T2. The output module 130 includes a first output unit 131 and a second output unit 132. The first output unit 131 includes a first output transistor T10, and the second output unit 132 includes a second output transistor T20. The output module 130 further includes a bootstrap unit 133. The bootstrap unit 133 includes a third transistor T3 and a bootstrap capacitor C1. The first control module 110 includes an input unit 111 and a third control unit 112, where the input unit 111 includes a fourth transistor T4, and the third control unit 112 includes a fifth transistor T5 and a sixth transistor T6. The first control module 110 further includes a seventh transistor T7. Different from FIG. 7, the first control module 110 in the shift register shown in FIG. 9 further includes a fourth control unit 113, and the fourth control unit 113 includes an eighth transistor T8 and a ninth transistor T9.

For parts of the shift register shown in FIG. 9 that have the same structure as those of the shift register shown in FIG. 7, a working process in each phase is the same as the working process of the shift register shown in FIG. 7, and will not be described in detail herein. The following only describes a working process of parts of the shift register shown in FIG. 9 that are different from those of the shift register shown in FIG. 7, that is, only describes a working process of the eighth transistor T8 and the ninth transistor T9 included in the fourth control unit 113 in each phase. Still using all the transistors in FIG. 9 being P-type transistors as an example, referring to FIG. 8 and FIG. 9, the working process of the shift register includes a first phase t1, a second phase t2, a third phase t3, a fourth phase t4, a transition phase to, a fifth phase t5, and a sixth phase t6.

In the first phase t1, potentials of the third node N3 and the first node N1 are at high levels; therefore, the eighth transistor T8 is turned off, and the first level signal VGH cannot be transmitted to the second node N2 via the eighth transistor T8 and the ninth transistor T9.

In the second phase t2, the potentials of the third node N3 and the first node N1 are at low levels, and therefore the eighth transistor T8 is turned on; the signal of the second clock signal terminal SCK2 is at a high level, the ninth transistor T9 is turned off, and the first level signal VGH cannot be transmitted to the second node N2 via the eighth transistor T8 and the ninth transistor T9.

In the third phase t3, the potentials of the third node N3 and the first node N1 are at low levels, and therefore the eighth transistor T8 is turned on; the signal of the second clock signal terminal SCK2 is at a high level, the ninth transistor T9 is turned off, and the first level signal VGH cannot be transmitted to the second node N2 via the eighth transistor T8 and the ninth transistor T9.

In the fourth phase t4, the potentials of the third node N3 and the first node N1 are at low levels, and therefore the eighth transistor T8 is turned on; the second clock signal terminal SCK2 is at a low level, the ninth transistor T9 is turned on, and the first level signal VGH is transmitted to the second node N2 via the eighth transistor T8 and the ninth transistor T9. In this way, when the potential of the first node N1 is at a low level, the second node N2 is set to a high level via the fourth control unit 113 (the eighth transistor T8 and the ninth transistor T9), and potential signals of the first node N1 and the second node N2 are mutually controlled, and potentials of internal nodes are kept stable.

In the transition phase t0, the potentials of the third node N3 and the first node N1 are at low levels, and therefore the eighth transistor T8 is turned on; the second clock signal is at a high level, the ninth transistor T9 is turned off, and the first level signal VGH cannot be transmitted to the second node N2 via the eighth transistor T8 and the ninth transistor T9.

In the fifth phase t5, the potentials of the third node N3 and the first node N1 are at low levels, and therefore the eighth transistor T8 is turned on; the signal of the second clock signal terminal SCK2 is at a high level, the ninth transistor T9 is turned off, and the first level signal VGH cannot be transmitted to the second node N2 via the eighth transistor T8 and the ninth transistor T9.

In the sixth phase t6, the potentials of the third node N3 and the first node N1 are at high levels; therefore, the eighth transistor T8 is turned off, and the first level signal VGH cannot be transmitted to the second node N2 via the eighth transistor T8 and the ninth transistor T9.

In one embodiment, when effective level pulses of the signal of the first clock signal terminal SCK1 and the signal of the second clock signal terminal SCK2 overlap, the signal of the first clock signal terminal SCK1, the signal of the second clock signal terminal SCK2, and the signal of the third clock signal terminal SCK3 have equal clock cycles, and within one of the clock cycles, the time of the effective level pulse is greater than a row cycle, where the row cycle is equal to a quotient of 1 to a refresh frequency, divided by a total number of rows of pixel circuits in a display panel.

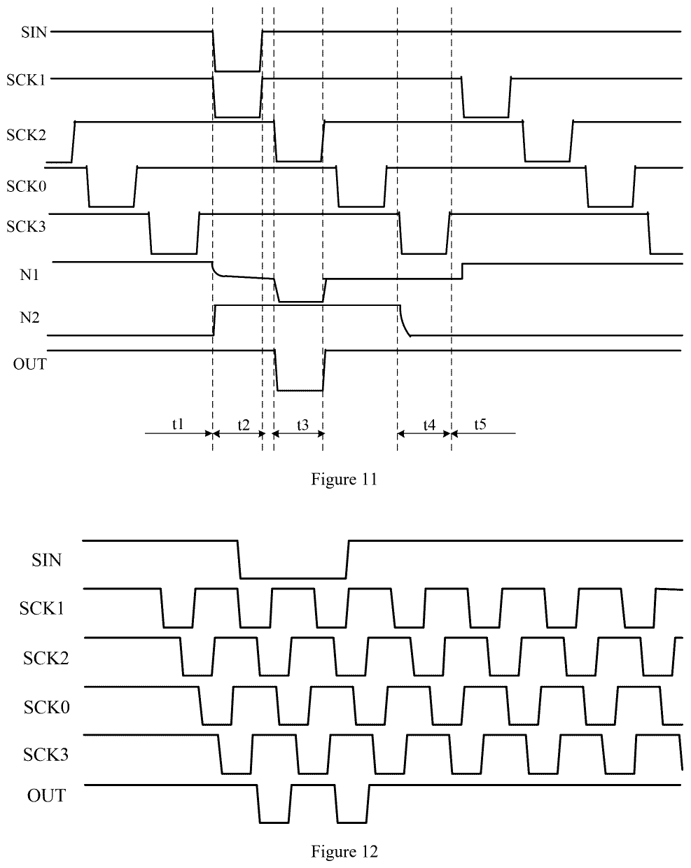

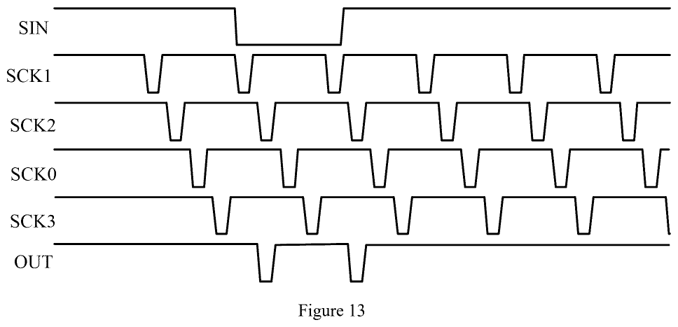

Specifically, a calculation formula of the row cycle is as follows:

$$h = \frac{1 / f}{w} ,$$

where h represents the row cycle, f represents the refresh frequency, and w represents the total number of rows of pixel circuits in the display panel. The total number of rows of pixel circuits in the display panel is equal to a sum of the number of rows of pixel circuits actually disposed in the display panel and a number of blank rows, where the blank rows do not actually exist in the display panel. FIG. 10 is a schematic diagram of a structure of a display panel according to an embodiment of the present application. Referring to FIG. 10, in the display panel, a column of pixel circuits is connected to two data lines (a first data line D1 and a second data line D2, respectively). For example, odd-numbered row pixel circuits 1 are connected to the first data line D1, and even-numbered row pixel circuits 1 are connected to the second data line D2. Each row of pixel circuits 1 is connected to an output terminal of a shift register 50 via a scanning line. The display panel structure shown in FIG. 10 is referred to as a dual data panel hereinafter. When the effective level pulses of the signal of the first clock signal terminal SCK1 and the signal of the second clock signal terminal SCK2 overlap, within one clock cycle, a time of an effective level pulse of each clock signal (including the signal of the first clock signal terminal SCK1, the signal of the second clock signal terminal SCK2, and the signal of the third clock signal terminal SCK3) is greater than the row cycle. In this way, when data is written into the second row of pixel circuits, data may also be written into the first row of pixel circuits, thereby increasing a data writing time for each row of pixel circuits, to meet application requirements of a display panel, such as the dual data panel.

In one embodiment, the cycles of the signal of the first clock signal terminal SCK1, the signal of the second clock signal terminal SCK2, and the signal of the third clock signal terminal SCK3 are equal to four times the row cycle, the signal of the second clock signal terminal SCK2 is delayed by one times the row cycle relative to the signal of the first clock signal terminal SCK1, and the signal of the third clock signal terminal SCK3 is delayed by two times the row cycle relative to the signal of the second clock signal terminal SCK2. Within one of the clock cycles, durations of the effective level pulses of the signal of the first clock signal terminal SCK1 and the signal of the second clock signal terminal SCK2 are greater than one times the row cycle and less than two times the row cycle.

Within one clock cycle, the time of the effective level pulse of each clock signal (including the signal of the first clock signal terminal SCK1, the signal of the second clock signal terminal SCK2, and the signal of the third clock signal terminal SCK3) is greater than the row cycle, and the signal of the second clock signal terminal SCK2 is delayed by one times the row cycle relative to the signal of the first clock signal terminal SCK1, and the effective level pulse of the signal of the second clock signal terminal SCK2 overlaps with the effective level pulse of the signal of the first clock signal terminal SCK1, thereby achieving overlap of effective level pulses output by two adjacent stages of shift registers in the gate drive circuit.

The durations of the effective level pulses of the signal of the first clock signal terminal SCK1 and the signal of the second clock signal terminal SCK2 are greater than one times the row cycle and less than two times the row cycle. In this case, when the shift register is applied to the scanning circuit and applied to the dual data panel, a duration of an effective level pulse in a scan signal output by the scanning circuit is greater than one times the row cycle, and a data writing time for each row of pixel circuits may be longer than the existing time of the display panel that is less than one times the row cycle. The duration of the effective level pulse in the scan signal output by the scanning circuit is less than two times the row cycle, which may reserve time for switching of control signals such as clock signals to ensure normal output of the scan signal.

FIG. 11 is a working timing diagram of another shift register according to an embodiment of the present application. The working timing is applicable to the shift register shown in FIG. 7. Still using all the transistors in the shift register shown in FIG. 7 being P-type transistors as an example, the first level signal VGH is a high level signal, and the second level signal VGL is a low level signal. Referring to FIG. 7 and FIG. 11, a working process of the shift register includes the following phases.

In a first phase t1, the initial signal SIN is always at a high level. When the signal of the third clock signal terminal SCK3 is at a low level, the second transistor T2 is turned on and transmits the second level signal VGL (low level signal) to the second node N2. The second output transistor T20 is turned on in response to the low level signal of the second node N2, and transmits the first level signal VGH (high level signal) to the output terminal of the shift register. That is, in the first phase t1, a signal output from the output terminal of the shift register is a high level signal.

In a second phase t2, the initial signal SIN and the signal of the first clock signal terminal SCK1 are both at low levels, the signal of the second clock signal terminal SCK2 is at a high level, and the signal of the third clock signal terminal SCK3 is at a high level. The first transistor T1 is turned on in response to the low level initial signal SIN, and transmits the high level signal of the third clock signal terminal SCK3 to the second node N2. The second transistor T2 is turned off in response to the high level signal of the third clock signal terminal SCK3. At the same time, the fourth transistor T4 is turned on in response to the low level signal of the first clock signal terminal SCK1, and transmits the low level initial signal SIN to the first node N1. The first output transistor T10 is turned on in response to the low level of the first node N1, and transmits the high level signal of the second clock signal terminal SCK2 to the output terminal of the shift register. Therefore, in the second phase t2, the output signal of the output terminal of the shift register is a high level signal.

In a third phase t3, the initial signal SIN and the signal of the first clock signal terminal SCK1 jump from low levels to high levels, the signal of the second clock signal terminal SCK2 jumps from a high level to a low level, and the signal of the third clock signal terminal SCK3 remains at a high level. The first transistor T1 is turned off based on the high level initial signal SIN. The second transistor T2 is turned off based on the high level signal of the third clock signal terminal SCK3. The output module 130 includes a storage capacitor C2 for maintaining a potential of the second node N2, and when the second control unit does not transmit a potential to the second node N2 (that is, when the first transistor T1 and the second transistor T2 are both turned off), the storage capacitor may maintain the potential of the second node N2, and the second node N2 remains at a high level. Therefore, both the fifth transistor T5 and the second output transistor T20 are turned off in response to the high level of the second node N2. The fourth transistor T4 is turned off in response to the high level signal of the first clock signal terminal SCK1. Because the signal of the second clock signal terminal SCK2 is always at a low level, the potential of the first node N1 is maintained at a low level by the bootstrap capacitor C1, and the first output transistor T10 remains on, and transmits the low level signal of the second clock signal terminal SCK2 to the output terminal of the shift register. Furthermore, before the signal of the third clock signal terminal SCK3 jumps to a low level, the shift register remains at the same level as the signal of the second clock signal terminal SCK2. Therefore, in the third phase t3, the output signal of the output terminal of the shift register is a low level signal.

In a fourth phase t4, the signal of the third clock signal terminal SCK3 jumps down to a low level, and the second transistor T2 is turned on in response to the low level signal of the third clock signal terminal SCK3, and transmits the second level signal VGL (low level signal) to the second node N2 of the shift register, and the fifth transistor T5 and the second output transistor T20 are turned on, and the second output transistor T20 transmits the first level signal VGH (high level signal) to the output terminal of the shift register. In this phase, the signal of the first clock signal terminal SCK1 and the signal of the second clock signal terminal SCK2 are both at high levels; therefore, the fourth transistor T4 is turned off, the sixth transistor T6 is also turned off, the first node N1 remains at a low level, and the first output transistor T10 is turned on and transmits the high level signal of the second clock signal terminal SCK2 to the output terminal of the shift register. Therefore, in the fourth phase t4, the output signal of the output terminal of the shift register is a high level signal.

In a fifth phase t5, the signal of the first clock signal terminal SCK1 jumps down to a low level, the initial signal SIN is at a high level, the signal of the third clock signal terminal SCK3 jumps to a high level, the second transistor T2 is turned off based on the high level signal of the third clock signal terminal SCK3, and the first transistor T1 is turned off based on the high level initial signal SIN, and therefore, the second node N2 remains at the low level of the previous phase, and the second output transistor T20 is turned on. The fourth transistor T4 is turned on in response to the low level signal of the first clock signal terminal SCK1, and transmits the high level initial signal SIN to the first node N1, and the third transistor T3 and the first output transistor T10 are turned off. The second node N2 still remains at a low level, the second output transistor T20 is turned on, and the output terminal of the shift register keeps outputting the first level signal VGH (high level signal). Therefore, in the fifth phase t5, the output signal of the output terminal of the shift register is a high level signal.

It should be noted that the working timing shown in FIG. 11 is a situation where the effective level pulse of the signal of the first clock signal terminal SCK1 does not overlap with the effective level pulse of the signal of the second clock signal terminal SCK2. It can be learned from the working timing shown in FIG. 11 that because the signal of the first clock signal terminal SCK1 does not overlap with the signal of the second clock signal terminal SCK2, the output signal of the shift register does not overlap with the initial signal SIN, and in the gate drive circuit, the initial signal SIN is an output signal of a previous stage of shift register. That is, in this embodiment, the signal of the first clock signal terminal SCK1 is set not to overlap with the signal of the second clock signal terminal SCK2, and there may be no overlap between effective level pulses of output signals of two adjacent stages of shift registers.

It should also be noted that, for the driving timing shown in FIG. 11, there are transition phases between the second stage t2 and the third stage t3, and between the third node t3 and the fourth stage t4. A working principle of the transition phase is similar to the working principle of the working timing shown in FIG. 8, and will not be described in detail herein.

The working timing shown in FIG. 11 is also applicable to the shift register shown in FIG. 9. For parts of the shift register shown in FIG. 9 that have the same structure as those of the shift register shown in FIG. 7, a working process in each phase is the same as the working process of the shift register shown in FIG. 7, and will not be described in detail herein. The following only describes a working process of parts of the shift register shown in FIG. 9 that are different from those of the shift register shown in FIG. 7, that is, only describes a working process of the eighth transistor T8 and the ninth transistor T9 included in the fourth control unit 113 in each phase. Still using all the transistors in FIG. 9 being P-type transistors as an example, referring to FIG. 9 and FIG. 11, the working process of the shift register includes a first phase t1, a second phase t2, a third phase t3, a fourth phase t4, and a fifth phase t5.

In the first phase t1, potentials of the third node N3 and the first node N1 are at high levels; therefore, the eighth transistor T8 is turned off, and the first level signal VGH cannot be transmitted to the second node N2 via the eighth transistor T8 and the ninth transistor T9.

In the second phase t2, the potentials of the third node N3 and the first node N1 are at low levels, and therefore the eighth transistor T8 is turned on; the signal of the second clock signal terminal SCK2 is at a high level, the ninth transistor T9 is turned off, and the first level signal VGH cannot be transmitted to the second node N2 via the eighth transistor T8 and the ninth transistor T9.

In the third phase t3, the potentials of the third node N3 and the first node N1 are at low levels, and therefore the eighth transistor T8 is turned on; the signal of the second clock signal terminal SCK2 is at a low level, the ninth transistor T9 is turned on, and the first level signal VGH is transmitted to the second node N2 via the eighth transistor T8 and the ninth transistor T9. In this way, when the potential of the first node N1 is at a low level, the second node N2 is set to a high level via the fourth control unit 113 (the eighth transistor T8 and the ninth transistor T9), and potential signals of the first node N1 and the second node N2 are mutually controlled, and potentials of internal nodes are kept stable.

In the fourth phase t4, the potentials of the third node N3 and the first node N1 are at low levels, and therefore the eighth transistor T8 is turned on; the signal of the second clock signal terminal SCK2 is at a high level, the ninth transistor T9 is turned off, and the first level signal VGH cannot be transmitted to the second node N2 via the eighth transistor T8 and the ninth transistor T9.

In the fifth phase t5, the potentials of the third node N3 and the first node N1 are at high levels; therefore, the eighth transistor T8 is turned off, and the first level signal VGH cannot be transmitted to the second node N2 via the eighth transistor T8 and the ninth transistor T9.

In one embodiment, the effective level pulses of the signal of the first clock signal terminal SCK1 and the signal of the second clock signal terminal SCK2 do not overlap, and the delay time of the signal of the third clock signal terminal SCK3 relative to the signal of the second clock signal terminal SCK2 is equal to m times the delay time of the signal of the second clock signal terminal SCK2 relative to the signal of the first clock signal terminal SCK1, where m is a positive integer.

When m is equal to 1, the delay time of the signal of the third clock signal terminal SCK3 relative to the signal of the second clock signal terminal SCK2 is equal to the delay time of the signal of the second clock signal terminal SCK2 relative to the signal of the first clock signal terminal SCK1. In some embodiments, the clock cycles of the signal of the first clock signal terminal SCK1, the signal of the second clock signal terminal SCK2, and the signal of the third clock signal terminal SCK3 are three times the row cycle, the delay time of the signal of the third clock signal terminal SCK3 relative to the signal of the second clock signal terminal SCK2 is equal to one times the row cycle, the delay time of the signal of the second clock signal terminal SCK2 relative to the signal of the first clock signal terminal SCK1 is also equal to one times the row cycle, and within one clock cycle, the duration of the effective level pulse of the clock signal is less than one times the row cycle. In some embodiments, the clock cycles of the signal of the first clock signal terminal SCK1, the signal of the second clock signal terminal SCK2, and the signal of the third clock signal terminal SCK3 are four times the row cycle, the delay time of the signal of the third clock signal terminal SCK3 relative to the signal of the second clock signal terminal SCK2 is equal to two times the row cycle, the delay time of the signal of the second clock signal terminal SCK2 relative to the signal of the first clock signal terminal SCK1 is equal to one times the row cycle, and within one clock cycle, the duration of the effective level pulse of the clock signal is less than one times the row cycle. In other embodiments of the present application, the clock cycles of the signal of the first clock signal terminal SCK1, the signal of the second clock signal terminal SCK2, and the signal of the third clock signal terminal SCK3 may be set to n (n is an integer greater than or equal to 4) times the row cycle, which is not specifically limited in this embodiment. The working timing shown in FIG. 11 corresponds to a situation where the clock cycles of the signal of the first clock signal terminal SCK1, the signal of the second clock signal terminal SCK2, and the signal of the third clock signal terminal SCK3 are four times the row cycle, and the delay time of the signal of the third clock signal terminal SCK3 relative to the signal of the second clock signal terminal SCK2 is equal to two times the row cycle.

Through the analysis processes of the working timing of the shift register shown in FIG. 8 and FIG. 11, it can be learned that the shift register of this embodiment may control whether effective level pulses of output signals of two adjacent stages of gate shift registers overlap by controlling the overlap or non-overlap of the effective level pulses of the signal of the first clock signal terminal SCK1 and the signal of the second clock signal terminal SCK2, thereby improving the flexibility of gate drive signals output by the gate drive circuit.

It should also be noted that the working timing shown in FIG. 8 and FIG. 11 shows an intermediate clock signal SCK0, and a delay time of the intermediate clock signal SCK0 relative to the signal of the second clock signal terminal SCK2 is equal to the delay time of the signal of the third clock signal terminal SCK3 relative to the signal of the second clock signal terminal SCK2. FIG. 12 is a working timing diagram of another shift register according to an embodiment of the present application, and FIG. 13 is a working timing diagram of another shift register according to an embodiment of the present application, both of which are suitable for driving the operation of the shift register of any of the above embodiments of the present application. Referring to FIG. 12 and FIG. 13, when a low level time interval of the initial signal SIN covers two consecutive low level time intervals in the first clock signal terminal SCK1, the third clock signal terminal SCK3, or the second clock signal terminal SCK2, the signal output by the output terminal OUT of the shift register includes two low levels.

From the above analysis, it can be learned that a number of pulses in the signal output by the output terminal OUT of the shift register is determined by a number of consecutive pulses in the first clock signal terminal SCK1, the second clock signal terminal SCK2, or the third clock signal terminal SCK3 covered by a pulse width of the initial signal SIN. By adjusting the signal pulse width of the initial signal SIN, a number of pulses in the scan signal output by the shift register may be adjusted, and the shift register provided in the embodiments of the present application can provide scan signals with a variety of numbers of pulses, further improving the flexibility of application of the shift register.

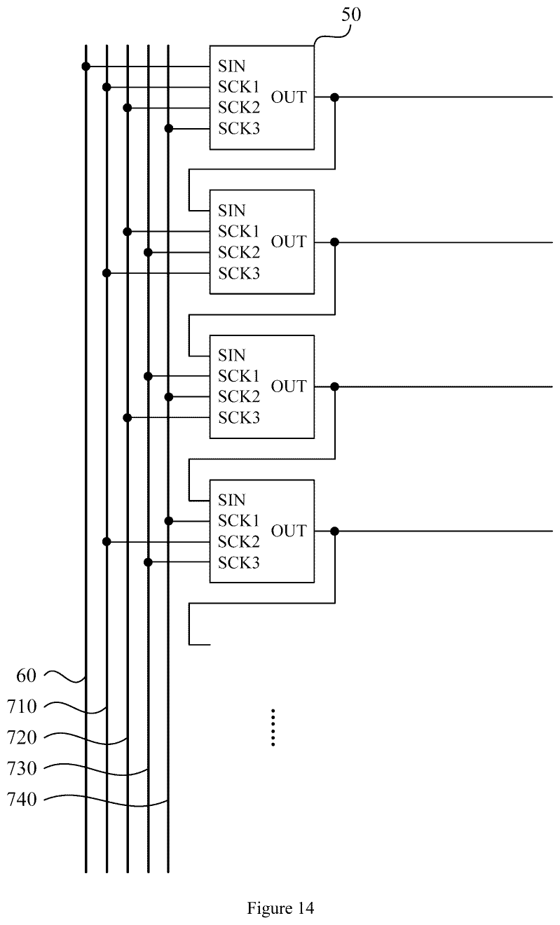

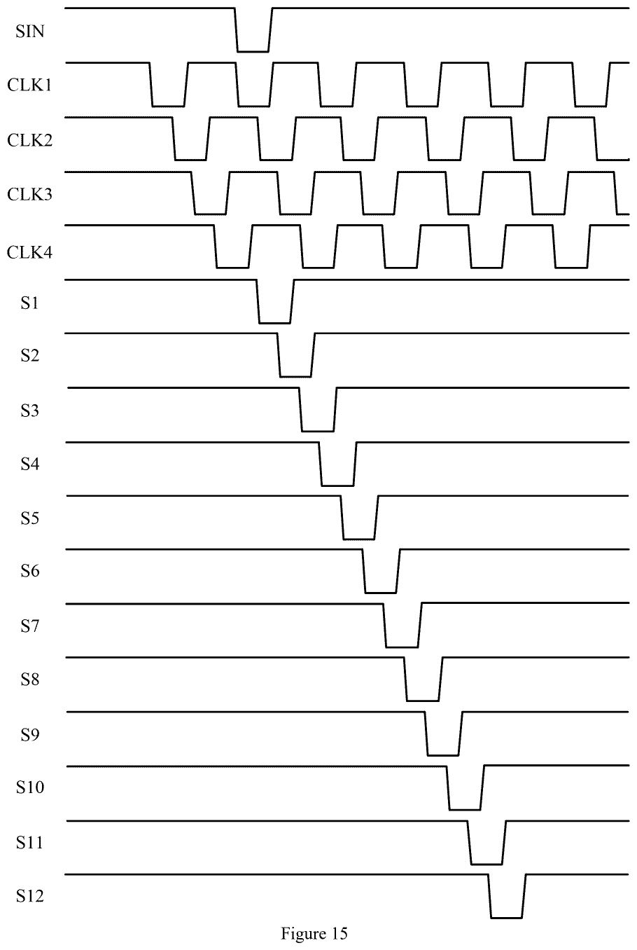

An embodiment of the present application further provides a gate drive circuit. FIG. 14 is a schematic diagram of a structure of a gate drive circuit according to an embodiment of the present application. Referring to FIG. 14, the gate drive circuit includes a plurality of stages of cascaded shift registers, and the shift register may be the shift register 50 of any of the above embodiments of the present application.

Referring to FIG. 14, the gate drive circuit further includes an initial signal line 60 (the initial signal line 60 is configured to transmit an initial signal SIN to a first stage of shift register, and an initial signal of another stage of shift register is an output signal of a previous stage of shift register) and a plurality of clock signal lines, and the plurality of clock signal lines include a first clock signal line 710, a second clock signal line 720, a third clock signal line 730, and a fourth clock signal line 740. The first clock signal line 710, the second clock signal line 720, the third clock signal line 730, and the fourth clock signal line 740 are configured to transmit clock signals whose timings are sequentially delayed.

FIG. 15 is a schematic diagram of driving timing of a gate drive circuit according to an embodiment of the present application. Referring to FIG. 14 and FIG. 15, the first clock signal line 710 is configured to transmit a first clock signal CLK1, the second clock signal line 720 is configured to transmit a second clock signal CLK2, the third clock signal line 730 is configured to transmit a third clock signal CLK3, and the fourth clock signal line 740 is configured to transmit a fourth clock signal CLK4, and pulse timings of the first clock signal CLK1, the second clock signal CLK2, the third clock signal CLK3, and the fourth clock signal CLK4 are sequentially delayed.

Further, a first clock signal terminal SCK1 of a (4n-3)^{th} stage of shift register 50 is connected to the first clock signal line 710, a second clock signal terminal SCK2 of the (4n-3)^{th} stage of shift register 50 is connected to the second clock signal line 720, and a third clock signal terminal SCK3 of the (4n-3)^{th} stage of shift register 50 is connected to the fourth clock signal line 740.

A first clock signal terminal SCK1 of a (4n-2)^{th} stage of shift register 50 is connected to the second clock signal line 720, a second clock signal terminal SCK2 of the (4n-2)^{th} stage of shift register 50 is connected to the third clock signal line 730, and a third clock signal terminal SCK3 of the (4n-2)^{th} stage of shift register 50 is connected to the first clock signal line 710.

A first clock signal terminal SCK1 of a (4n-1)^{th} stage of shift register 50 is connected to the third clock signal line 730, a second clock signal terminal SCK2 of the (4n-1)^{th} stage of shift register 50 is connected to the fourth clock signal line 740, and the third clock signal terminal SCK3 of the (4n-1)^{th} stage of shift register 50 is connected to the second clock signal line 720.

A first clock signal terminal SCK1 of a 4n^{th} stage of shift register 50 is connected to the fourth clock signal line 740, a second clock signal terminal SCK2 of the 4n^{th} stage of shift register 50 is connected to the first clock signal line 710, and a third clock signal terminal SCK3 of the 4n^{th} stage of shift register 50 is connected to the third clock signal line 730, where n is an integer greater than or equal to 1, and 4n is less than or equal to a total number of shift registers 50.

FIG. 14 only shows a 1^{st} to 4^{th} stages of shift registers 50 in the display panel, satisfying the case of n=1. In practical applications, the display panel may include a plurality of stages of shift registers 50, and every 4 stages of shift registers 50 constitute a cycle, and timings of on-levels of the first clock signal terminal SCK1, the second clock signal terminal SCK2, and the third clock signal terminal SCK3 of each stage of shift register 50 are sequentially delayed, and in two adjacent stages of shift registers 50, an arrival time of an on-level of a first clock signal terminal SCK1 of a current stage of shift register 50 is later than an arrival time of an on-level of a first clock signal terminal SCK1 of a previous stage of shift register 50, an arrival time of an on-level of a second clock signal terminal SCK2 of the current stage of shift register 50 is later than an arrival time of an on-level of a second clock signal terminal SCK2 of the previous stage of shift register 50, and an arrival time of an on-level of a third clock signal terminal SCK3 of the current stage of shift register 50 is later than an arrival time of an on-level of a third clock signal terminal SCK3 of the previous stage of the shift register 50. FIG. 15 schematically shows waveforms of scan signals S1 to S12 output by the 1^{st} to 12^{th} stages of shift registers 50 in the display panel. It can be learned that the plurality of cascaded shift registers 50 in this embodiment of the present application achieves stage-by-stage output of scan signals with timings sequentially shifted backward.

Referring to FIG. 14 and FIG. 15, further, the first clock signal line 710, the second clock signal line 720, the third clock signal line 730, and the fourth clock signal line 740 are configured to transmit clock signals whose timings are sequentially delayed by a preset unit duration, where the preset duration is greater than or equal to ½ of a duration corresponding to an effective level pulse of the clock signal.

For example, using the preset duration equal to a row cycle h as an example, the cycles of the first clock signal CLK1, the second clock signal CLK2, the third clock signal CLK3, and the fourth clock signal CLK4 are all 4 h, the pulse timings of the first clock signal CLK1, the second clock signal CLK2, the third clock signal CLK3, and the fourth clock signal CLK4 are sequentially delayed by h, and the durations of the effective level pulses of the first clock signal CLK1, the second clock signal CLK2, the third clock signal CLK3, and the fourth clock signal CLK4 are W, and 0<W<2h. In one embodiment, h<W<2h is set. In this way, clock signal requirements of the first clock signal terminal SCK1, the second clock signal terminal SCK2, and the third clock signal terminal SCK3 of each stage of shift register 50 can be satisfied.

In this embodiment of the present application, through adjustment of the duration of the effective level pulse of the initial signal SIN provided by the initial signal line 60 to the first stage of shift register 50, and the timings of the first clock signal CLK1, the second clock signal CLK2, the third clock signal CLK3, and the fourth clock signal CLK4, the shift register 50 in the display panel can provide diversified scan signals.

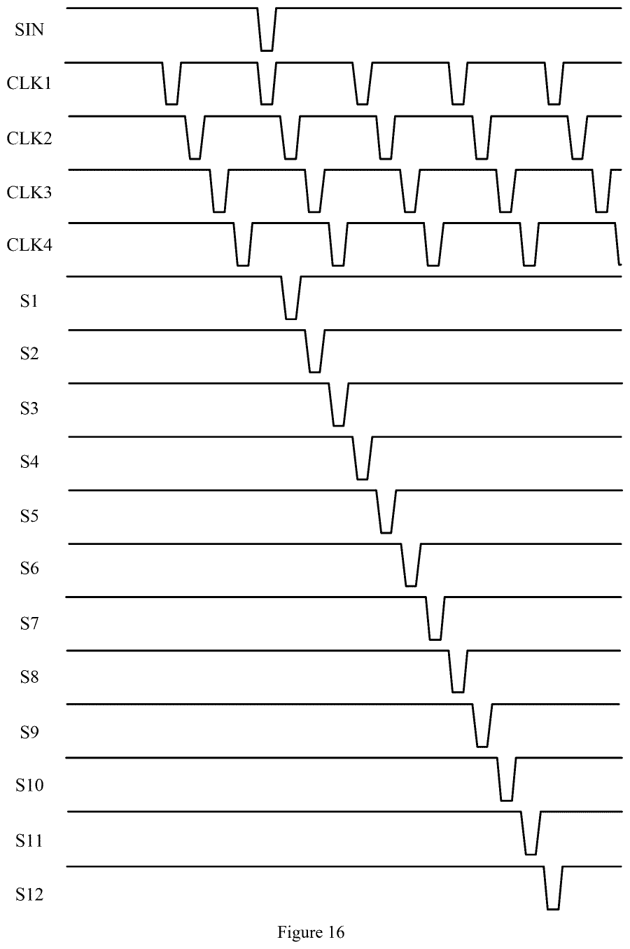

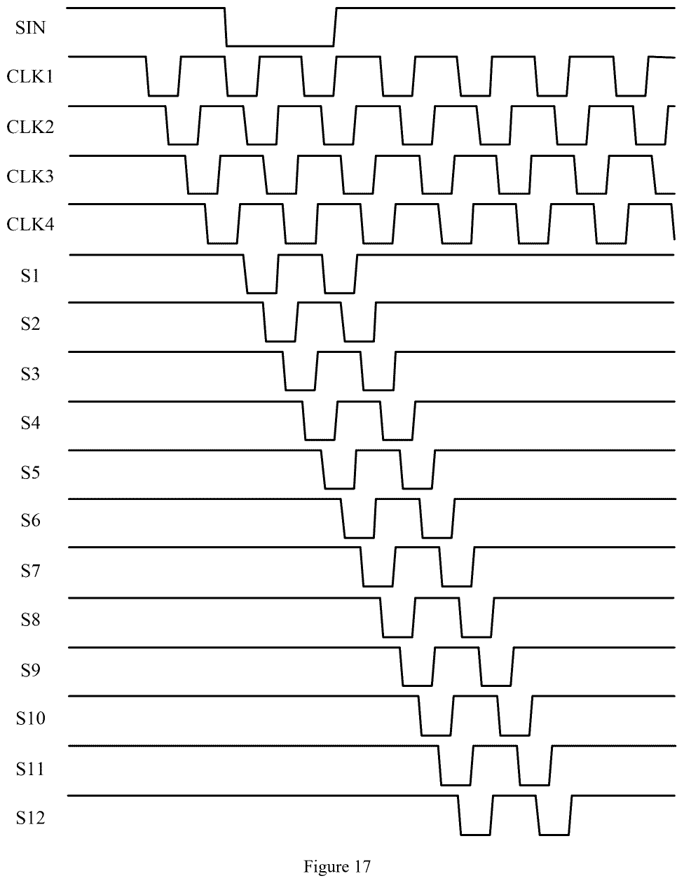

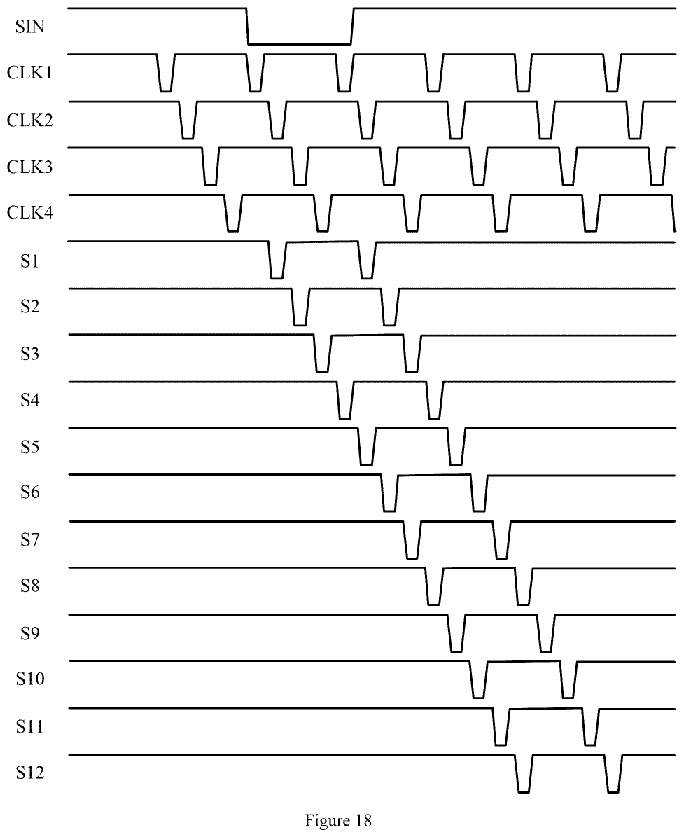

FIG. 16 is a driving timing diagram of another display panel according to an embodiment of the present application. FIG. 17 is a driving timing diagram of another display panel according to an embodiment of the present application. FIG. 18 is a driving timing diagram of another display panel according to an embodiment of the present application.

FIG. 15 and FIG. 16 both show a time interval of the effective level pulse of the initial signal SIN of the first stage of shift register 50, covering a time interval of an effective level pulse in the first clock signal CLK1, the second clock signal CLK2, the third clock signal CLK3, and the fourth clock signal CLK4. Referring to FIG. 14 and FIG. 15, when the pulse timings of the first clock signal CLK1 and the second clock signal CLK2 overlap, the pulse timings of the second clock signal CLK2 and the third clock signal CLK3 overlap, and when the pulse timings of the third clock signal CLK3 and the fourth clock signal CLK4 overlap, pulse timings of scan signals output by two adjacent stages of shift registers 50 overlap. Referring to FIG. 14 and FIG. 16, when the pulse timings of the first clock signal CLK1, the second clock signal CLK2, the third clock signal CLK3, and the fourth clock signal CLK4 do not overlap, the pulse timings of the scan signals output by two adjacent stages of shift registers 50 do not overlap.

FIG. 17 and FIG. 18 both show the time interval of the effective level pulse of the initial signal SIN of the first stage of shift register 50, covering the time interval of two adjacent effective level pulses in the first clock signal CLK1, and the scan signal output by each stage of shift register 50 includes two effective level pulses. When the time interval of the effective level pulse of the initial signal SIN of the first stage of shift register 50 covers a time interval of m consecutive effective level pulses in the first clock signal CLK1, the scan signal output by each stage of shift register 50 includes p effective level pulses. In one embodiment, 1≤p≤4.

Referring to FIG. 14 and FIG. 17, when the pulse timings of the first clock signal CLK1 and the second clock signal CLK2 overlap, the pulse timings of the second clock signal CLK2 and the third clock signal CLK3 overlap, and when the pulse timings of the third clock signal CLK3 and the fourth clock signal CLK4 overlap, pulse timings of scan signals output by two adjacent stages of shift registers 50 overlap. Referring to FIG. 14 and FIG. 18, when the pulse timings of the first clock signal CLK1, the second clock signal CLK2, the third clock signal CLK3, and the fourth clock signal CLK4 do not overlap, the pulse timings of the scan signals output by two adjacent stages of shift registers 50 do not overlap.

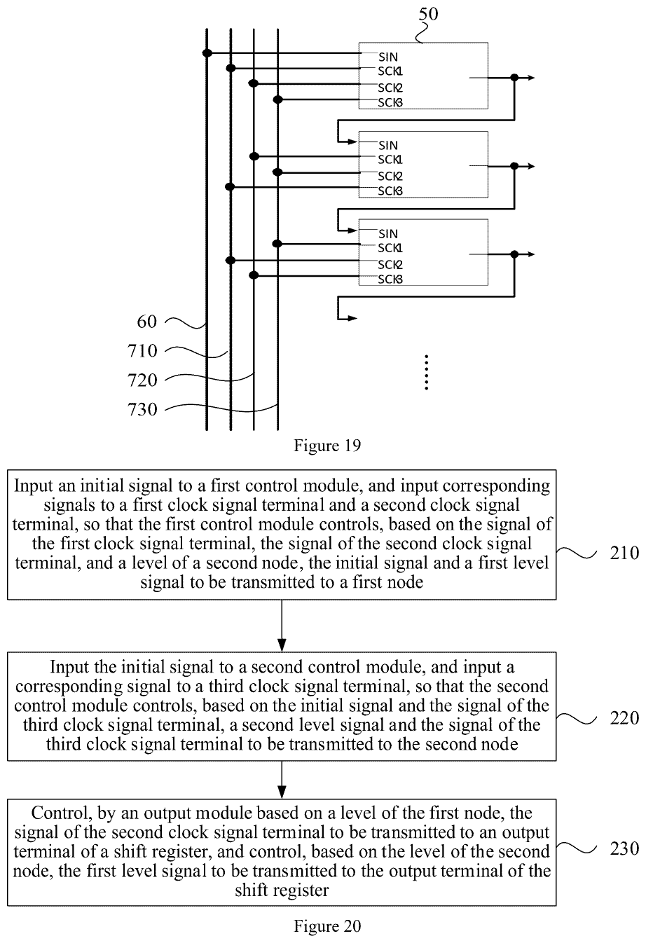

However, it should be noted that when the effective level pulses of the first clock signal and the second clock signal input to each stage of shift register do not overlap, three clock signal lines may also be provided. FIG. 19 is a schematic diagram of a structure of another gate drive circuit according to an embodiment of the present application. Referring to FIG. 19, when effective level pulses of a signal of a first clock signal terminal SCK1 and a signal of a second clock signal terminal SCK2 input to each stage of shift register do not overlap, the gate drive circuit may include an initial signal line 60, a first clock signal line 710, a second clock signal line 720, and a third clock signal line 730. Starting from a first stage of shift register, every three stages of cascaded shift registers constitute a register group. In each register group, a signal of a first clock signal terminal SCK1 of the first stage of shift register is provided by the first clock signal line 710, a signal of a second clock signal terminal SCK2 is provided by the second clock signal line 720, and a signal of a third clock signal terminal SCK3 is provided by the third clock signal line 730; a signal of a first clock signal terminal SCK1 of a second stage of shift register is provided by the second clock signal line 720, a signal of a second clock signal terminal SCK2 is provided by the third clock signal line 730, and a signal of a third clock signal terminal SCK3 is provided by the first clock signal line 710; a signal of a first clock signal terminal SCK1 of a third stage of shift register is provided by the third clock signal line 730, a signal of a second clock signal terminal SCK2 is provided by the first clock signal line 710, and a signal of a third clock signal terminal SCK3 is provided by the second clock signal line 720.

An embodiment of the present application further provides a driving method for a gate drive circuit. The driving method for a gate drive circuit is used to drive the gate drive circuit of the above embodiments of the present application. FIG. 20 is a flowchart of a driving method for a gate drive circuit according to an embodiment of the present application. Referring to FIG. 20, the driving method for a gate drive circuit includes:

Step 210: Input an initial signal to a first control module, and input corresponding signals to a first clock signal terminal and a second clock signal terminal, and the first control module controls, based on the signal of the first clock signal terminal, the signal of the second clock signal terminal, and a level of a second node, the initial signal and a first level signal to be transmitted to a first node.

Step 220: Input the initial signal to a second control module, and input a corresponding signal to a third clock signal terminal, and the second control module controls, based on the initial signal and the signal of the third clock signal terminal, a second level signal and the signal of the third clock signal terminal to be transmitted to the second node.

Step 230: Control, by an output module based on a level of the first node, the signal of the second clock signal terminal to be transmitted to an output terminal of the shift register, and control, based on the level of the second node, the first level signal to be transmitted to the output terminal of the shift register.

An effective level pulse of the second clock signal terminal is delayed relative to an effective level pulse of the first clock signal terminal, and a delay time is greater than or equal to ½ of a time corresponding to the effective level pulse. An effective level pulse of the third clock signal terminal is delayed relative to the effective level pulse of the second clock signal terminal. An effective level pulse of the initial signal overlaps with an effective level pulse of the signal of the first clock signal terminal.

In one embodiment, cycles of a first clock signal, a second clock signal, and a third clock signal are equal to four times a row cycle, the second clock signal is delayed by one times the row cycle relative to the first clock signal, and the third clock signal is delayed by two times the row cycle relative to the second clock signal. Within one clock cycle, durations of effective level pulses of the first clock signal and the second clock signal are greater than one times the row cycle and less than two times the row cycle.

In one embodiment, the effective level pulses of the first clock signal and the second clock signal do not overlap; a delay time of the third clock signal relative to the second clock signal is equal to m times the delay time of the second clock signal relative to the first clock signal, where m is a positive integer.

The embodiments of the present application further provide the driving method for a gate drive circuit, which is used to drive the gate drive circuit of the above embodiments of the present application and has the beneficial effects of the gate drive circuit of any of the above embodiments of the present application.

The application is not limited to the particular embodiments described herein and that various changes, readjustments, and substitutions can be made without departing from the scope of protection of the present application. Therefore, although the present application has been described in detail through the above embodiments, the present application is not limited to the above embodiments, and can also include more other equivalent embodiments without departing from the concept of the disclosure, and the scope of the present application is determined by the scope of the appended claims.

1. A shift register, comprising:
a first control module, a second control module, and an output module, wherein an output terminal of the first control module is connected to a first node, and an output terminal of the second control module is connected to a second node;
the first control module is configured to control, based on a signal of a first clock signal terminal, a signal of a second clock signal terminal, and a level of the second node, an initial signal and a first level signal to be transmitted to the first node;
the second control module is configured to control, based on the initial signal and a signal of a third clock signal terminal, a second level signal and the signal of the third clock signal terminal to be transmitted to the second node; and
the output module is configured to control, based on a level of the first node, the signal of the second clock signal terminal to be transmitted to an output terminal of the shift register, and control, based on the level of the second node, the first level signal to be transmitted to the output terminal of the shift register, wherein
an effective level pulse of the second clock signal terminal is delayed relative to an effective level pulse of the first clock signal terminal, and a delay time is greater than or equal to ½ of a time corresponding to the effective level pulse; an effective level pulse of the third clock signal terminal is delayed relative to the effective level pulse of the second clock signal terminal; and an effective level pulse of the initial signal overlaps with an effective level pulse of the signal of the first clock signal terminal.

2. The shift register according to claim 1, wherein an effective level pulse of the signal of the third clock signal terminal does not overlap with an effective level pulse of the signal of the second clock signal terminal; and
the second control module is configured to set the level of the second node to an ineffective level based on the signal of the third clock signal terminal and the initial signal after the level of the first node jumps to an effective level and before the effective level pulse of the signal of the second clock signal terminal arrives.

3. The shift register according to claim 1, wherein the second control module comprises a first control unit and a second control unit, wherein the first control unit is configured to control, based on the initial signal, the signal of the third clock signal terminal to be transmitted to the second node, and the second control unit is configured to control, based on the signal of the third clock signal terminal, the second level signal to be transmitted to the second node.

4. The shift register according to claim 3, wherein the first control unit comprises a first transistor, a gate of the first transistor is connected to the initial signal, a first electrode of the first transistor is connected to the signal of the third clock signal terminal, and a second electrode of the first transistor is electrically connected to the second node; and the second control unit comprises a second transistor, a gate of the second transistor is connected to the signal of the third clock signal terminal, a first electrode of the second transistor is connected to the second level signal, and a second electrode of the second transistor is electrically connected to the second node.

5. The shift register according to claim 1, wherein the output module comprises a first output unit and a second output unit, wherein a control terminal of the first output unit is electrically connected to the first node, a first terminal of the first output unit is connected to the signal of the second clock signal terminal, and a second terminal of the first output unit is electrically connected to the output terminal of the shift register; and
a control terminal of the second output unit is electrically connected to the second node, a first terminal of the second output unit is connected to the first level signal, and a second terminal of the second output unit is electrically connected to the output terminal of the shift register.

6. The shift register according to claim 5, wherein the output module further comprises a bootstrap unit, wherein the bootstrap unit is configured to couple the level of the first node based on a voltage change of the signal of the second clock signal terminal.

7. The shift register according to claim 6, wherein the bootstrap unit comprises a third transistor and a bootstrap capacitor, wherein a gate of the third transistor is electrically connected to the first node, a first electrode of the third transistor is connected to the signal of the second clock signal terminal, a second electrode of the third transistor is connected to a first terminal of the bootstrap capacitor, and a second terminal of the bootstrap capacitor is electrically connected to the first node.

8. The shift register according to claim 1, wherein the first control module comprises an input unit and a third control unit, wherein the input unit is configured to control, based on the signal of the first clock signal terminal connected to a control terminal of the input unit, the initial signal to be transmitted to the first node; and
the third control unit is configured to control, based on the level of the second node and the signal of the second clock signal terminal, the first level signal to be transmitted to the first node.

9. The shift register according to claim 8, wherein the input unit comprises a fourth transistor, wherein a gate of the fourth transistor is connected to the signal of the first clock signal terminal, a first electrode of the fourth transistor is connected to the initial signal, and a second electrode of the fourth transistor is electrically connected to the first node.

10. The shift register according to claim 9, wherein the third control unit comprises a fifth transistor and a sixth transistor, wherein a gate of the fifth transistor is electrically connected to the second node, a first electrode of the fifth transistor is connected to the first level signal, and a second electrode of the fifth transistor is electrically connected to a first electrode of the sixth transistor; and
a gate of the sixth transistor is connected to the signal of the second clock signal terminal, and a second electrode of the sixth transistor is electrically connected to the first node.

11. The shift register according to claim 10, wherein the first control module further comprises a seventh transistor, wherein a gate of the seventh transistor is connected to the second level signal, and the second electrode of the fourth transistor and the second electrode of the sixth transistor are separately electrically connected to the first node via the seventh transistor.

12. The shift register according to claim 8, wherein the first control module further comprises a fourth control unit, wherein the fourth control unit is configured to control, based on a potential of the first node and the signal of the second clock signal terminal, the first level signal to be transmitted to the second node.

13. The shift register according to claim 12, wherein the fourth control unit comprises an eighth transistor and a ninth transistor, wherein a gate of the eighth transistor is electrically connected to the first node, a first electrode of the eighth transistor is connected to the first level signal, and a second electrode of the eighth transistor is electrically connected to a first electrode of the ninth transistor; and
a gate of the ninth transistor is connected to the second clock signal terminal, and a second electrode of the ninth transistor is electrically connected to the second node.

14. The shift register according to claim 1, wherein the first level signal and the second level signal are each a fixed signal, and the first level signal and the second level signal have opposite levels.

15. A gate drive circuit, comprising:
a plurality of stages of cascaded shift registers comprising:
a first control module, a second control module, and an output module, wherein an output terminal of the first control module is connected to a first node, and an output terminal of the second control module is connected to a second node;
the first control module is configured to control, based on a signal of a first clock signal terminal, a signal of a second clock signal terminal, and a level of the second node, an initial signal and a first level signal to be transmitted to the first node;
the second control module is configured to control, based on the initial signal and a signal of a third clock signal terminal, a second level signal and the signal of the third clock signal terminal to be transmitted to the second node; and
the output module is configured to control, based on a level of the first node, the signal of the second clock signal terminal to be transmitted to an output terminal of the shift register, and control, based on the level of the second node, the first level signal to be transmitted to the output terminal of the shift register, wherein
an effective level pulse of the second clock signal terminal is delayed relative to an effective level pulse of the first clock signal terminal, and a delay time is greater than or equal to ½ of a time corresponding to the effective level pulse; an effective level pulse of the third clock signal terminal is delayed relative to the effective level pulse of the second clock signal terminal; and an effective level pulse of the initial signal overlaps with an effective level pulse of the signal of the first clock signal terminal, wherein
the gate drive circuit further comprises: a first clock signal line, a second clock signal line, a third clock signal line, and a fourth clock signal line, wherein the first clock signal line, the second clock signal line, the third clock signal line, and the fourth clock signal line are configured to transmit clock signals whose timings are sequentially delayed;
a first clock signal terminal of a (4n-3)^{th} stage of shift register is connected to the first clock signal line, a second clock signal terminal of the (4n-3)^{th} stage of shift register is connected to the second clock signal line, and a third clock signal terminal of the (4n-3)^{th} stage of shift register is connected to the fourth clock signal line;
a first clock signal terminal of a (4n-2)^{th} stage of shift register is connected to the second clock signal line, a second clock signal terminal of the (4n-2)^{th} stage of shift register is connected to the third clock signal line, and a third clock signal terminal of the (4n-2)^{th} stage of shift register is connected to the first clock signal line;
a first clock signal terminal of a (4n-1)^{th} stage of shift register is connected to the third clock signal line, a second clock signal terminal of the (4n-1)^{th} stage of shift register is connected to the fourth clock signal line, and a third clock signal terminal of the (4n-1)^{th} stage of shift register is connected to the second clock signal line;
a first clock signal terminal of a 4n^{th} stage of shift register is connected to the fourth clock signal line, a second clock signal terminal of the 4n^{th} stage of shift register is connected to the first clock signal line, and a third clock signal terminal of the 4n^{th} stage of shift register is connected to the third clock signal line, wherein
n is an integer greater than or equal to 1, and 4n is less than or equal to a total number of shift registers; and
the first clock signal line, the second clock signal line, the third clock signal line, and the fourth clock signal line are configured to transmit clock signals whose timings are sequentially delayed by a preset duration, wherein the preset duration is greater than or equal to ½ of a duration corresponding to an effective level pulse of the clock signal.

16. A driving method for a gate drive circuit, comprising:
inputting an initial signal to a first control module, and inputting corresponding signals to a first clock signal terminal and a second clock signal terminal, wherein the first control module controls, based on the signal of the first clock signal terminal, the signal of the second clock signal terminal, and a level of a second node, the initial signal and a first level signal to be transmitted to a first node;
inputting the initial signal to a second control module, and inputting a corresponding signal to a third clock signal terminal, wherein the second control module controls, based on the initial signal and the signal of the third clock signal terminal, a second level signal and the signal of the third clock signal terminal to be transmitted to the second node; and
controlling, by an output module based on a level of the first node, the signal of the second clock signal terminal to be transmitted to an output terminal of the shift register, and controlling, based on the level of the second node, the first level signal to be transmitted to the output terminal of the shift register, wherein
an effective level pulse of the second clock signal terminal is delayed relative to an effective level pulse of the first clock signal terminal, and a delay time is greater than or equal to ½ of a time corresponding to the effective level pulse; an effective level pulse of the third clock signal terminal is delayed relative to the effective level pulse of the second clock signal terminal; and an effective level pulse of the initial signal overlaps with an effective level pulse of the signal of the first clock signal terminal.

17. The driving method for a gate drive circuit according to claim 16, wherein an effective level pulse of the signal of the first clock signal terminal overlaps with an effective level pulse of the signal of the second clock signal terminal.

18. The driving method for a gate drive circuit according to claim 17, wherein the signal of the first clock signal terminal, the signal of the second clock signal terminal, and the signal of the third clock signal terminal have equal clock cycles, and within one of the clock cycles, the time of the effective level pulse is greater than a row cycle, wherein the row cycle is equal to a quotient of 1 to a refresh frequency, divided by a total number of rows of pixel circuits in a display panel.

19. The driving method for a gate drive circuit according to claim 18, wherein the cycles of the signal of the first clock signal terminal, the signal of the second clock signal terminal, and the signal of the third clock signal terminal are equal to four times the row cycle, the signal of the second clock signal terminal is delayed by one times the row cycle relative to the signal of the first clock signal terminal, and the signal of the third clock signal terminal is delayed by two times the row cycle relative to the signal of the second clock signal terminal; and
within one of the clock cycles, durations of the effective level pulses of the signal of the first clock signal terminal and the signal of the second clock signal terminal are greater than one times the row cycle and less than two times the row cycle.

20. The driving method for a gate drive circuit according to claim 16, wherein the effective level pulse of the signal of the first clock signal terminal does not overlap with the effective level pulse of the signal of the second clock signal terminal; and a delay time of the signal of the third clock signal terminal relative to the signal of the second clock signal terminal is equal to m times the delay time of the signal of the second clock signal terminal relative to the signal of the first clock signal terminal, wherein m is a positive integer.
